(19) United States
(12) Patent Application Publication
(10) Pub. No.: US 2023/0402511 A1
(43) Pub. Date: Dec. 14, 2023

(54) SEMICONDUCTOR DEVICE AND MANUFACTURING METHOD OF SEMICONDUCTOR DEVICE

(71) Applicant: FUJI ELECTRIC CO., LTD., Kanagawa (JP)

(72) Inventors: Motoyoshi KUBOUCHI, Matsumoto-city (JP); Takashi YOSHIMURA, Matsumoto-city (JP); Yuki SAWA, Matsumoto-city (JP); Shogo YAMAGUCHI, Matsumoto-city (JP)

(21) Appl. No.: 18/455,643

(22) Filed: Aug. 25, 2023

Related U.S. Application Data
(63) Continuation of application No. PCT/JP2022/034599, filed on Sep. 15, 2022.

(30) Foreign Application Priority Data
Sep. 15, 2021 (JP) 2021-150249

(51) Int. Cl. H01L 29/32; H01L 29/739; H01L 29/06; H01L 21/265; H01L 21/322; H01L 29/861; H01L 29/66

(52) U.S. Cl. CPC H01L 29/32; H01L 29/7395; H01L 29/0603; H01L 21/265; H01L 21/322; H01L 29/8613; H01L 29/66333

(57) ABSTRACT

Provided is a semiconductor device including a drift region, a buffer region which is provided in a back surface side of a semiconductor substrate relative to the drift region and has a first peak of a doping concentration, and a first lattice defect region which is provided in a front surface side of the semiconductor substrate relative to the first peak in a depth direction of the semiconductor substrate, in which the buffer region has a hydrogen peak which is provided in the front surface side of the semiconductor substrate relative to the first lattice defect region, and an integrated concentration obtained by integrating the doping concentration in a direction from an upper end of the drift region to the hydrogen peak in the depth direction of the semiconductor substrate is equal to or larger than a critical integrated concentration.

### BACKGROUND

### 1. Technical Field

The present invention relates to a semiconductor device and a manufacturing method of the semiconductor device.

### 2. Related Art

Conventionally, there is known a semiconductor device having peaks formed by hydrogen ion implantation (see, for example, Patent Documents 1, 2, and 3).

### PRIOR ART DOCUMENTS

### Patent Documents

Patent Document 1: WO 2019/181852
Patent Document 2: Japanese Patent Application Publication No. 2018-107303
Patent Document 3: Japanese Patent Application Publication No. 2022-035157

### BRIEF DESCRIPTION OF THE DRAWINGS

FIG. 1A shows an example of a top view of a semiconductor device 100.

FIG. 1B shows an example of a cross section a-a′ in FIG. 1A.

FIG. 2A shows an example of a doping concentration distribution in a collector region 22, a buffer region 20, and a drift region 18.

FIG. 2B shows a modified example of the semiconductor device 100.

FIG. 2C shows a modified example of the semiconductor device 100.

FIG. 2D shows a modified example of the semiconductor device 100.

FIG. 2E shows a modified example of the semiconductor device 100.

FIG. 2F shows a modified example of the semiconductor device 100.

FIG. 2G shows a modified example of the doping concentration distribution in a first lattice defect region 161.

FIG. 2H shows a modified example of the doping concentration distribution in the first lattice defect region 161.

FIG. 3A shows an example of the semiconductor device 100 including a first lifetime control region 151.

FIG. 3B shows a modified example of the semiconductor device 100 including the first lifetime control region 151.

FIG. 3C shows a modified example of the semiconductor device 100 including the first lifetime control region 151.

FIG. 3D shows a modified example of the semiconductor device 100 including the first lifetime control region 151.

FIG. 3E shows a modified example of the semiconductor device 100 including the first lifetime control region 151.

FIG. 3F shows a modified example of the semiconductor device 100 including the first lifetime control region 151.

FIG. 3G shows a modified example of the semiconductor device 100 including the first lifetime control region 151.

FIG. 3H shows a modified example of the semiconductor device 100 including the first lifetime control region 151.

FIG. 3I shows a modified example of the semiconductor device 100 including the first lifetime control region 151.

FIG. 4 shows an example of the doping concentration distribution in a semiconductor substrate 10.

FIG. 5A shows a top view of a modified example of the semiconductor device 100.

FIG. 5B shows a cross section b-b′ of the modified example of the semiconductor device 100.

FIG. 6A is a flowchart showing an example of a manufacturing process of the semiconductor device 100.

FIG. 6B is a flowchart showing a modified example of the manufacturing process of the semiconductor device 100.

FIG. 6C is a flowchart showing a modified example of the manufacturing process of the semiconductor device 100.

FIG. 7 is a diagram for describing electrical characteristics of the semiconductor device 100.

### DESCRIPTION OF EXEMPLARY EMBODIMENTS

Hereinafter, the invention will be described through embodiments of the invention, but the following embodiments do not limit the invention according to claims. In addition, not all combinations of features described in the embodiment are essential to the solving means of the invention.

As used herein, one side in a direction parallel to a depth direction of a semiconductor substrate is referred to as “upper” and the other side is referred to as “lower”. One surface of two principal surfaces of a substrate, a layer, or another member is referred to as an upper surface, and the other surface is referred to as a lower surface. “Upper” and “lower” directions are not limited to a direction of gravity, or a direction in which a semiconductor device is mounted.

In the present specification, technical matters may be described using orthogonal coordinate axes consisting of an X axis, a Y axis, and a Z axis. The orthogonal coordinate axes merely specify relative positions of components, and do not limit a specific direction. For example, the Z axis is not limited to indicate a height direction with respect to the ground. Note that a +Z axis direction and a −Z axis direction are directions opposite to each other. When the Z axis direction is described without describing the signs, it means that the direction is parallel to the +Z axis and the −Z axis.

In the present specification, orthogonal axes parallel to the upper surface and the lower surface of the semiconductor substrate are referred to as the X axis and the Y axis. Further, an axis perpendicular to the upper surface and the lower surface of the semiconductor substrate is referred to as the Z axis. In the present specification, the direction of the Z axis may be referred to as the depth direction. Further, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting a conductivity type of the P type.

In the present specification, a doping concentration means a concentration of the acceptor or a concentration of the donor electrically activated in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}-N_{A}. In the present specification, the net doping concentration may be simply referred to as the doping concentration.

The donor has a function of supplying electrons to a semiconductor. The acceptor has a function of receiving electrons from the semiconductor. The donor and the acceptor are not limited to the impurities themselves. For example, a VOH defect which is a combination of a vacancy (V), oxygen (O), and hydrogen (H) existing in the semiconductor functions as the donor that supplies electrons. In the present specification, the VOH defect may be referred to as a hydrogen donor. In other words, a case where electrons are supplied by hydrogen to cause it to function as the donor may be referred to as the hydrogen donor.

In the present specification, the N type bulk donor is distributed throughout the semiconductor substrate. The bulk donor is a dopant donor substantially uniformly contained in an ingot during the manufacture of the ingot from which the semiconductor substrate is made. The bulk donor of the present example is an element other than hydrogen. The dopant of the bulk donor is, for example, phosphorus, antimony, arsenic, selenium, or sulfur, but the invention is not limited to these. The bulk donor of the present example is phosphorus. The bulk donor may also be contained in the P type region. The semiconductor substrate may be a wafer cut out from a semiconductor ingot, or may be a chip obtained by singulating the wafer. The semiconductor ingot may be manufactured by either a Chokralsky method (CZ method), a magnetic field applied Chokralsky method (MCZ method), or a float zone method (FZ method). The ingot in the present example is manufactured by the MCZ method. An oxygen concentration contained in a substrate manufactured by the MCZ method may be 1×10¹⁷ to 7×10¹⁷/cm³. An oxygen concentration contained in a substrate manufactured by the FZ method may be 1×10¹⁵ to 5×10¹⁶/cm³. When the oxygen concentration is high, hydrogen donors tend to be easily generated. The bulk donor concentration may be expressed using a chemical concentration of the bulk donor distributed throughout the semiconductor substrate, or may take a value between 90% and 100% of the chemical concentration. Further, for the semiconductor substrate, a non-doped substrate which does not contain a dopant such as phosphorus may be used. In that case, the bulk donor concentration (DO) of the non-doped substrate is, for example, from 1×10¹⁰/cm³ or more and to 5×10¹²/cm³ or less. The bulk donor concentration (DO) of the non-doped substrate may preferably be 1×10¹¹/cm³ or more. The bulk donor concentration (DO) of the non-doped substrate may preferably be 5×10¹²/cm³ or less. Note that the respective concentrations in the present invention may be values obtained at room temperature. As the value at room temperature, a value at 300 K (Kelvin) (about 26.9° C.) may be used as an example. The semiconductor substrate may contain, in the entire semiconductor substrate, acceptor atoms at a concentration lower than the bulk donor concentration. In this case, the conductivity type of the semiconductor substrate is the N type.

In the present specification, a description of a P+ type or an N+ type means a higher doping concentration than that of the P type or the N type, and a description of a P− type or an N− type means a lower doping concentration than that of the P type or the N type. Further, in the specification, a description of a P++ type or an N++ type means a higher doping concentration than that of the P+ type or the N+ type.

A chemical concentration in the present specification indicates an atomic density of an impurity measured regardless of an electrical activation state. The chemical concentration can be measured by, for example, secondary ion mass spectrometry (SIMS). The net doping concentration described above can be measured by capacitance-voltage profiling (CV profiling). Further, a carrier concentration measured by spreading resistance profiling (SRP method) may be set as the net doping concentration. The carrier concentration measured by the CV profiling or the SRP method may be a value in a thermal equilibrium state. Further, in a region of an N type, the donor concentration is sufficiently higher than the acceptor concentration, and thus the carrier concentration of the region may be set as the donor concentration. Similarly, in a region of a P type, the carrier concentration of the region may be set as the acceptor concentration. In the present specification, the doping concentration of the N type region may be referred to as the donor concentration, and the doping concentration of the P type region may be referred to as the acceptor concentration.

Further, when a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or/cm³ are used for presenting the concentration per unit volume. This unit is used for a concentration of a donor or an acceptor in a semiconductor substrate, or a chemical concentration. The notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The reduction in carrier mobility occurs when carriers are scattered due to disorder (disorder) of a crystal structure due to a lattice defect or the like.

The concentration of the donor or the acceptor calculated from the carrier concentration measured by the CV profiling or the SRP method may be lower than a chemical concentration of an element indicating the donor or the acceptor. As an example, in a silicon semiconductor, a donor concentration of phosphorus or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen. In the present specification, an SI unit system is adopted. In the present specification, a unit of a distance or length may be expressed in cm (centimeters). In this case, the calculations may be performed after conversion into m (meters).

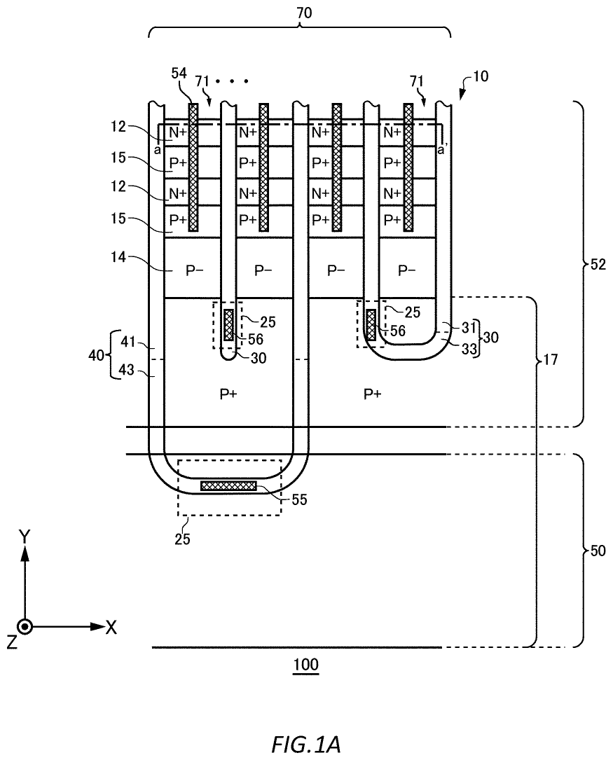

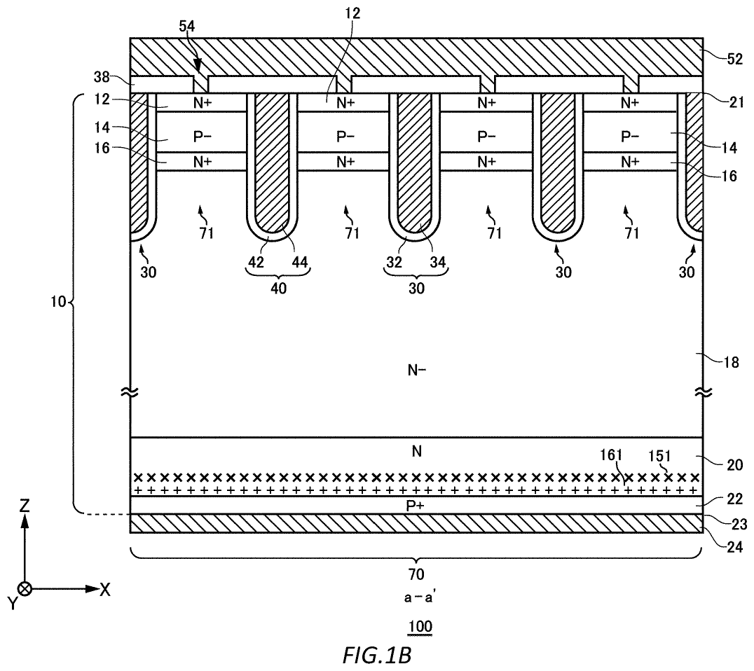

FIG. 1A shows an example of a top view of a semiconductor device 100. The semiconductor device 100 of the present example is a semiconductor chip that includes a transistor portion 70.

The transistor portion 70 is a region obtained by projecting a collector region 22 provided on a back surface side of a semiconductor substrate 10 onto an upper surface of the semiconductor substrate 10. The collector region 22 will be described later. The transistor portion 70 includes a transistor such as an IGBT.

FIG. 1A shows a surrounding region of a chip end portion, which is an edge side of the semiconductor device 100, and the other regions are omitted. For example, an edge termination structure portion may be provided in a region on a negative side of the Y axis direction in the semiconductor device 100 of the present example. The edge termination structure portion reduces an electric field strength on the upper surface side of the semiconductor substrate 10. The edge termination structure portion has a structure of, for example, a guard ring, a field plate, RESURF, and a combination of these. Note that although the present example describes the edge on the negative side in the Y axis direction for convenience, the same applies to other edges of the semiconductor device 100.

The semiconductor substrate 10 may be a silicon substrate, may be a silicon carbide substrate, or may be a nitride semiconductor substrate such as gallium nitride, or the like. The semiconductor substrate 10 of the present example is a silicon substrate.

The semiconductor device 100 of the present example includes, at the front surface 21 of the semiconductor substrate 10, a gate trench portion 40, a dummy trench portion 30, an emitter region 12, a base region 14, a contact region 15, and a well region 17. The front surface 21 will be described later. In addition, the semiconductor device 100 of the present example includes an emitter electrode 52 and a gate metal layer 50 provided above the front surface 21 of the semiconductor substrate 10.

The emitter electrode 52 is provided above the gate trench portion 40, the dummy trench portion 30, the emitter region 12, the base region 14, the contact region 15, and the well region 17. In addition, the gate metal layer 50 is provided above the gate trench portion 40 and the well region 17.

The emitter electrode 52 and the gate metal layer 50 are formed of a material containing metal. At least a partial region of the emitter electrode 52 may be formed of metal such as aluminum (Al) or a metal alloy such as an aluminum-silicon alloy (AlSi) and an aluminum-silicon-copper alloy (AlSiCu). At least a partial region of the gate metal layer 50 may be formed of metal such as aluminum (Al) or a metal alloy such as an aluminum-silicon alloy (AlSi) and an aluminum-silicon-copper alloy (AlSiCu). The emitter electrode 52 and the gate metal layer 50 may have a barrier metal formed of titanium, a titanium compound, or the like below a region formed of aluminum or the like. The emitter electrode 52 and the gate metal layer 50 are provided separately from each other.

The emitter electrode 52 and the gate metal layer 50 are provided above the semiconductor substrate 10 with an interlayer dielectric film 38 interposed therebetween. The interlayer dielectric film 38 is omitted in FIG. 1A. The interlayer dielectric film 38 is provided with contact holes 54, contact holes 55, and contact holes 56 penetrating therethrough.

The contact holes 55 connect the gate metal layer 50 and the gate conductive portions inside the transistor portions 70. Inside the contact hole 55, a plug formed of tungsten or the like may be formed.

The contact hole 56 connects the emitter electrode 52 and a dummy conductive portion in the dummy trench portion 30. Inside the contact hole 56, a plug formed of tungsten or the like may be formed.

A connection portion 25 electrically connects the emitter electrode 52 or a front surface side electrode of the gate metal layer 50 or the like with the semiconductor substrate 10. In one example, the connection portion 25 is provided between the gate metal layer 50 and the gate conductive portion. The connection portion 25 is also provided between the emitter electrode 52 and the dummy conductive portion. The connection portion 25 is formed of a conductive material such as polysilicon doped with impurities. The connection portion 25 of the present example is polysilicon doped with an N type impurity (N+). The connection portion 25 is provided above the front surface 21 of the semiconductor substrate 10 via a dielectric film such as an oxide film, or the like.

The gate trench portions 40 are arrayed at predetermined intervals along a predetermined array direction (the X axis direction in the present example). The gate trench portion 40 of the present example may include: two extending portions 41 which extend along an extending direction (the Y axis direction in the present example) parallel to the front surface 21 of the semiconductor substrate 10 and perpendicular to the array direction; and a connecting portion 43 which connects the two extending portions 41.

Preferably, at least a part of the connecting portion 43 is formed in a curved shape. By connecting end portions of the two extending portions 41 of the gate trench portion 40, an electric field strength at the end portions of the extending portions 41 can be reduced. At the connecting portion 43 of the gate trench portion 40, the gate metal layer 50 may be connected to the gate conductive portion.

The dummy trench portion 30 is a trench portion electrically connected with the emitter electrode 52. Similar to the gate trench portions 40, the dummy trench portions 30 are arrayed at predetermined intervals along a predetermined array direction (the X axis direction in the present example). The dummy trench portion 30 of the present example may have, similar to the gate trench portion 40, a U shape at the front surface 21 of the semiconductor substrate 10. That is, the dummy trench portion 30 may include two extending portions 31 which extend along the extending direction and a connecting portion 33 which connects the two extending portions 31.

The transistor portion 70 of the present example has a structure of repeatedly arrayed two gate trench portions 40 and three dummy trench portions 30. That is, the transistor portion 70 of the present example includes the gate trench portions 40 and the dummy trench portions 30 at a ratio of 2:3. For example, the transistor portion 70 includes one extending portion 31 between two extending portions 41. In addition, the transistor portion 70 includes two extending portions 31 adjacent to the gate trench portion 40.

It is to be noted that the ratio between the gate trench portions 40 and the dummy trench portions 30 is not limited to the present example. The ratio of the gate trench portions 40 and the dummy trench portions 30 may be 1:1 or may be 2:4. Alternatively, with all trench portions being the gate trench portions 40, the transistor portion 70 does not need to include the dummy trench portion 30.

The well region 17 is a region of a second conductivity type which is provided in the front surface 21 side of the semiconductor substrate 10 relative to the drift region 18 to be described later. The well region 17 is an example of a well region provided on an edge side of the semiconductor device 100. As an example, the well region 17 is of the P+ type. The well region 17 is formed within a predetermined range from an end portion of an active region on a side on which the gate metal layer 50 is provided. The well region 17 may have a diffusion depth larger than the depths of the gate trench portion 40 and the dummy trench portion 30. Partial regions of the gate trench portion 40 and the dummy trench portion 30 on the gate metal layer 50 side are formed in the well region 17. Bottoms of ends of the gate trench portion 40 and the dummy trench portion 30 in the extending direction may be covered by the well region 17.

The contact hole 54 is formed above each region of the emitter region 12 and the contact region 15 in the transistor portion 70. The contact hole 54 is not provided above the well region 17 provided at both ends of the Y axis direction. In this manner, one or more contact holes 54 are formed in the interlayer dielectric film. The one or more contact holes 54 may be provided to extend in the extending direction.

A mesa portion 71 is a mesa portion provided in direct contact with the trench portion in a plane parallel to the front surface 21 of the semiconductor substrate 10. The mesa portion is a portion of the semiconductor substrate 10 interposed between two trench portions adjacent to each other, and may be a portion ranging from the front surface 21 of the semiconductor substrate 10 to the depth of the lowermost bottom portion of each trench portion. The extending portions of each trench portion may be set to be one trench portion. That is, the region sandwiched between two extending portions may be set to be a mesa portion.

The mesa portion 71 is provided in direct contact with at least one of the dummy trench portion 30 and the gate trench portion 40 in the transistor portion 70. The mesa portion 71 includes the well region 17, the emitter region 12, the base region 14, and the contact region 15 at the front surface 21 of the semiconductor substrate 10. In the mesa portion 71, the emitter region 12 and the contact region 15 are provided alternately in the extending direction.

The base region 14 is a region of the second conductivity type provided in the front surface 21 side of the semiconductor substrate 10. As an example, the base region 14 is of the P− type. The base region 14 may be provided at both end portions of the mesa portion 71 in the Y axis direction, at the front surface 21 of the semiconductor substrate 10. Note that FIG. 1A shows only one end portion in the Y axis direction of the base region 14.

The emitter region 12 is a region of the first conductivity type which has a higher doping concentration than the drift region 18. As an example, the emitter region 12 of the present example is of the N+ type. An example of a dopant of the emitter region 12 is arsenic (As). The emitter region 12 is provided in contact with the gate trench portion 40 at the front surface 21 in the mesa portion 71. The emitter region 12 may be provided to extend in the X axis direction from one of two trench portions sandwiching the mesa portion 71 to the other one of the two trench portions. The emitter region 12 is also provided below the contact hole 54.

In addition, the emitter region 12 may or may not be in contact with the dummy trench portion 30. The emitter region 12 of the present example is in contact with the dummy trench portion 30.

The contact region 15 is a region of the second conductivity type having a higher doping concentration than that of the base region 14. As an example, the contact region 15 of the present example is of the P+ type. The contact region 15 of the present example is provided at the front surface 21 of the mesa portion 71. The contact region 15 may be provided in the X axis direction from one of two trench portions sandwiching the mesa portion 71 to the other one of the two trench portions. The contact region 15 may or may not be in contact with the gate trench portion 40 or the dummy trench portion 30. The contact region 15 of the present example is in contact with the dummy trench portion 30 and the gate trench portion 40. The contact region 15 is also provided below the contact hole 54.

FIG. 1B shows an example of a cross section a-a′ in FIG. 1A. The cross section a-a′ is an XZ plane passing through the emitter region 12 in the transistor portion 70. In the cross section a-a′, the semiconductor device 100 of the present example includes the semiconductor substrate 10, the interlayer dielectric film 38, the emitter electrode 52, and the collector electrode 24. The emitter electrode 52 is formed above the semiconductor substrate 10 and the interlayer dielectric film 38.

The drift region 18 is a region of the first conductivity type which is provided in the semiconductor substrate 10. As an example, the drift region 18 of the present example is of the N− type. The drift region 18 may be a region that has remained without other doping regions being formed in the semiconductor substrate 10. That is, a doping concentration D_{dr} of the drift region 18 may be a doping concentration of the semiconductor substrate 10.

The buffer region 20 is a region of the first conductivity type which is provided in the back surface 23 side of the semiconductor substrate 10 relative to the drift region 18. As an example, the buffer region 20 of the present example is of the N type. A doping concentration of the buffer region 20 may be higher than the doping concentration D_{dr} of the drift region 18. The doping concentration of the buffer region 20 may be higher than the bulk donor concentration. The buffer region 20 may function as a field stop layer which prevents a depletion layer extending from the lower surface side of the base regions 14 from reaching the collector region 22 of the second conductivity type.

The collector region 22 is provided below the buffer region 20 in the transistor portion 70. The collector region 22 is of the second conductivity type. As an example, the collector region 22 of the present example is of the P+ type.

The collector electrode 24 is formed at the back surface 23 of the semiconductor substrate 10. The collector electrode 24 is formed of a conductive material such as metal.

The base region 14 is a region of the second conductivity type which is provided above the drift region 18. The base region 14 is provided in contact with the gate trench portion 40. The base region 14 may be provided in contact with the dummy trench portion 30.

The emitter region 12 is provided between the base region 14 and the front surface 21. The emitter region 12 is provided in contact with the gate trench portion 40. The emitter region 12 may or may not be in contact with the dummy trench portion 30.

An accumulation region 16 is a region of the first conductivity type provided in the front surface 21 side of the semiconductor substrate 10 relative to the drift region 18. As an example, the accumulation region 16 of the present example is of the N+ type. Note that the accumulation region 16 does not need to be provided.

In addition, the accumulation region 16 is provided in contact with the gate trench portion 40. The accumulation region 16 may or may not be in contact with the dummy trench portion 30. A doping concentration of the accumulation region 16 is higher than the doping concentration D_{dr} of the drift region 18. An ion implantation dose amount of the accumulation region 16 may be 1.0 E12 cm⁻² or more and 1.0 E13 cm⁻² or less. Alternatively, the ion implantation dose amount of the accumulation region 16 may be 3.0 E12 cm⁻² or more and 6.0 E12 cm⁻² or less. By providing the accumulation region 16, a carrier injection enhancement effect (IE effect) can be enhanced to reduce an ON voltage of the transistor portion 70. Note that E means a power of 10, and 1.0 E12 cm⁻² means, for example, 1.0×10¹² cm⁻².

One or more gate trench portions 40 and one or more dummy trench portions 30 are provided at the front surface 21. Each trench portion is provided from the front surface 21 to the drift region 18. In a region where at least any of the emitter region 12, the base region 14, the contact region 15, or the accumulation region 16 is provided, each trench portion also penetrates through these regions to reach the drift region 18. The configuration of the trench portion penetrating through the doping region is not limited to that manufactured in the order of forming the doping region and then forming the trench portion. The configuration of the trench portion penetrating through the doping region also includes a configuration of the doping region being formed between the trench portions after forming the trench portions.

The gate trench portion 40 includes a gate trench, a gate dielectric film 42, and a gate conductive portion 44 formed at the front surface 21. The gate dielectric film 42 is formed to cover an inner wall of the gate trench. The gate dielectric film 42 may be formed by oxidizing or nitriding a semiconductor on the inner wall of the gate trench. The gate conductive portion 44 is formed inside from the gate dielectric film 42 in the gate trench. The gate dielectric film 42 insulates the gate conductive portion 44 from the semiconductor substrate 10. The gate conductive portion 44 is formed of a conductive material such as polysilicon. The gate trench portion 40 is covered by the interlayer dielectric film 38 on the front surface 21.

The gate conductive portion 44 includes a region opposing the adjacent base region 14 on the mesa portion 71 side with the gate dielectric film 42 being interposed therebetween, in the depth direction of the semiconductor substrate 10. When a predetermined voltage is applied to the gate conductive portion 44, a channel is formed by an electron inversion layer in a surface layer of the base region 14 in contact with the gate trench.

The dummy trench portion 30 may have the same structure as the gate trench portion 40. The dummy trench portion 30 includes a dummy trench, a dummy dielectric film 32, and a dummy conductive portion 34 formed in the front surface 21 side. The dummy dielectric film 32 is formed to cover an inner wall of the dummy trench. The dummy conductive portion 34 is formed in the dummy trench, and is formed inside the dummy dielectric film 32. The dummy dielectric film 32 insulates the dummy conductive portion 34 from the semiconductor substrate 10. The dummy trench portion 30 is covered by the interlayer dielectric film 38 on the front surface 21.

The interlayer dielectric film 38 is provided on the front surface 21. The emitter electrode 52 is provided above the interlayer dielectric film 38. In the interlayer dielectric film 38, one or more contact holes 54 are provided for electrically connecting the emitter electrode 52 with the semiconductor substrate 10. The contact hole 55 and the contact hole 56 may similarly be provided so as to penetrate through the interlayer dielectric film 38.

The first lattice defect region 161 is a region including a lattice defect formed by hydrogen ion implantation from the back surface 23 side. The first lattice defect region 161 functions as a lifetime killer. In the first lattice defect region 161, by reducing a turn-off time of the semiconductor device 100 and suppressing a tail current, losses during switching can be reduced. Details of the first lattice defect region 161 will be described later. Note that whether the first lattice defect region 161 is formed by hydrogen ion implantation can be specified by an analysis of the chemical concentration of the semiconductor device 100, and the like. For example, the lifetime killer formed by helium ion implantation can be specified by detecting helium.

The lifetime killer is a recombination center of charge carriers. In the present specification, the charge carriers may simply be referred to as carriers. The lifetime killer may be a lattice defect. For example, the lifetime killer may be a vacancy, a divacancy, a defect complex of these with elements configuring the semiconductor substrate 10, or dislocation. That is, the first lattice defect region 161 is a region including the recombination center.

A lifetime killer concentration is a concentration at the recombination center of carriers. The lifetime killer concentration may be a concentration of the lattice defect. For example, the lifetime killer concentration may be a vacancy concentration of a vacancy, a divacancy, or the like, may be a defect complex concentration of these vacancies with elements configuring the semiconductor substrate 10, or may be a dislocation concentration. That is, the first lattice defect region 161 may be a region including the lifetime killer.

The first lifetime control region 151 is a region where a lifetime killer is intentionally formed by implanting an impurity into the semiconductor substrate 10, or the like. A noble gas element such as helium and neon may be used as the lifetime killer. The lifetime killer concentration is a concentration at the recombination center, but may alternatively be a chemical concentration of the noble gas element such as helium and neon. The first lifetime control region 151 of the present example is formed by implanting helium into the semiconductor substrate 10.

The first lifetime control region 151 is provided in the back surface 23 side relative to a center of the semiconductor substrate 10 in the depth direction of the semiconductor substrate 10. The first lifetime control region 151 of the present example is provided in the buffer region 20. The first lifetime control region 151 can be formed without using a mask when formed on the entire surface of the semiconductor substrate 10 in the XY plane. The first lifetime control region 151 may be provided in a part of the semiconductor substrate 10 in the XY plane using a mask having a predetermined shape.

In addition, the first lifetime control region 151 of the present example is formed by the implantation from the back surface 23 side. Accordingly, an effect on the front surface 21 side of the semiconductor device 100 can be avoided. For example, the first lifetime control region 151 is formed by irradiating helium from the back surface 23 side. Herein, which of the front surface 21 side and the back surface 23 side the implantation is performed from for forming the first lifetime control region 151 can be determined by acquiring a state of the semiconductor substrate 10 by the SRP method or a measurement of an inter-collector-emitter leakage current. Note that the inter-collector-emitter leakage current may simply be referred to as a leakage current.

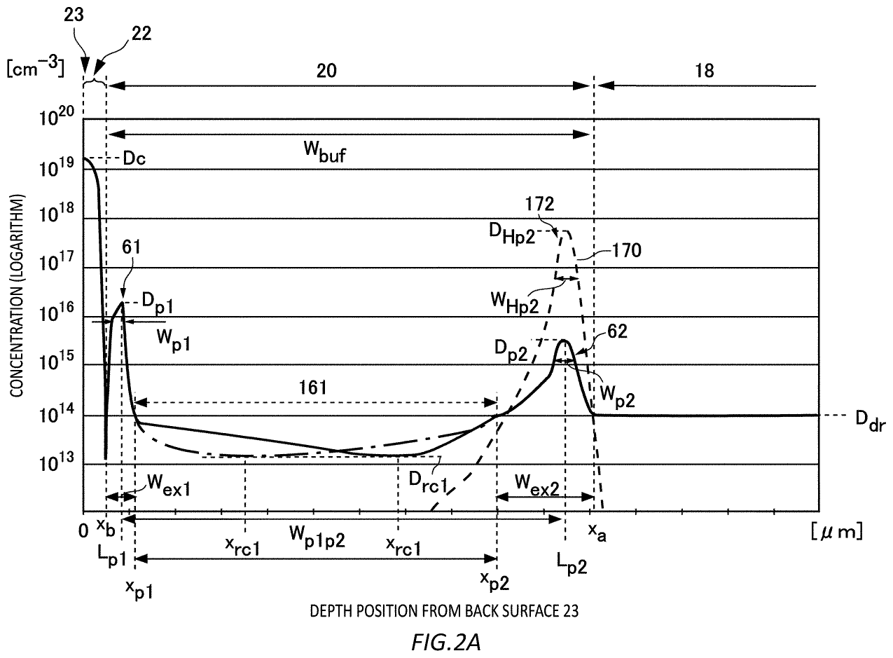

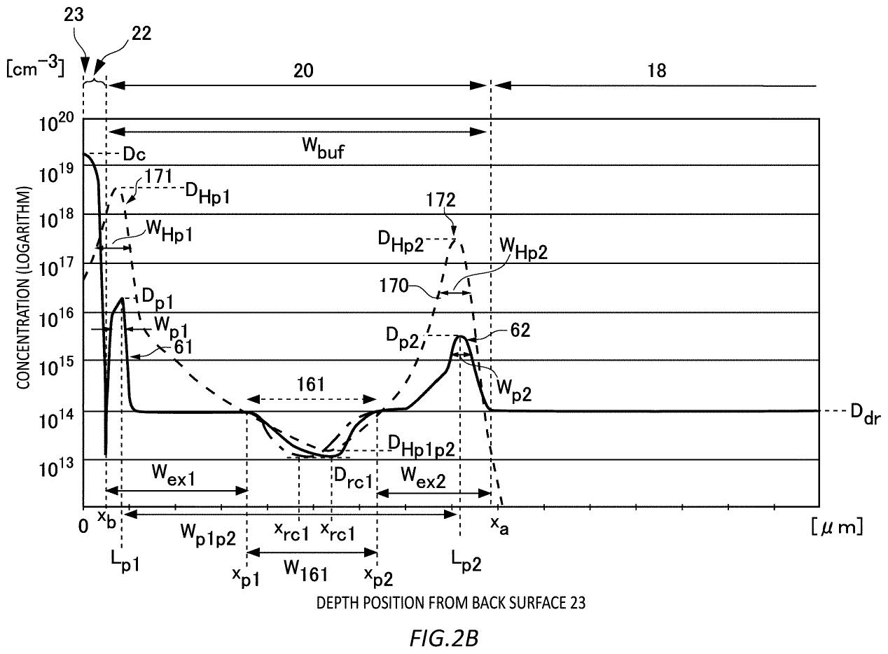

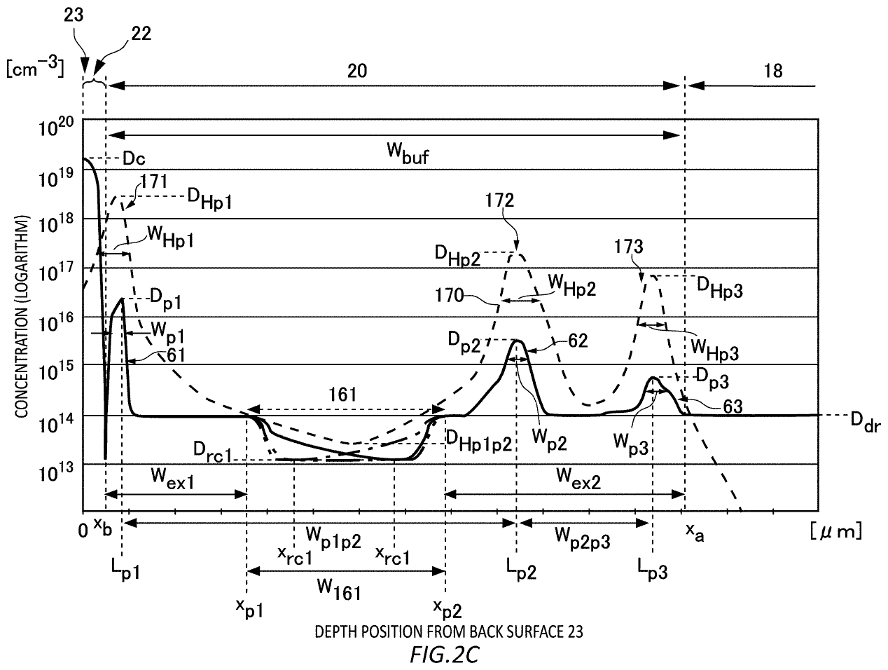

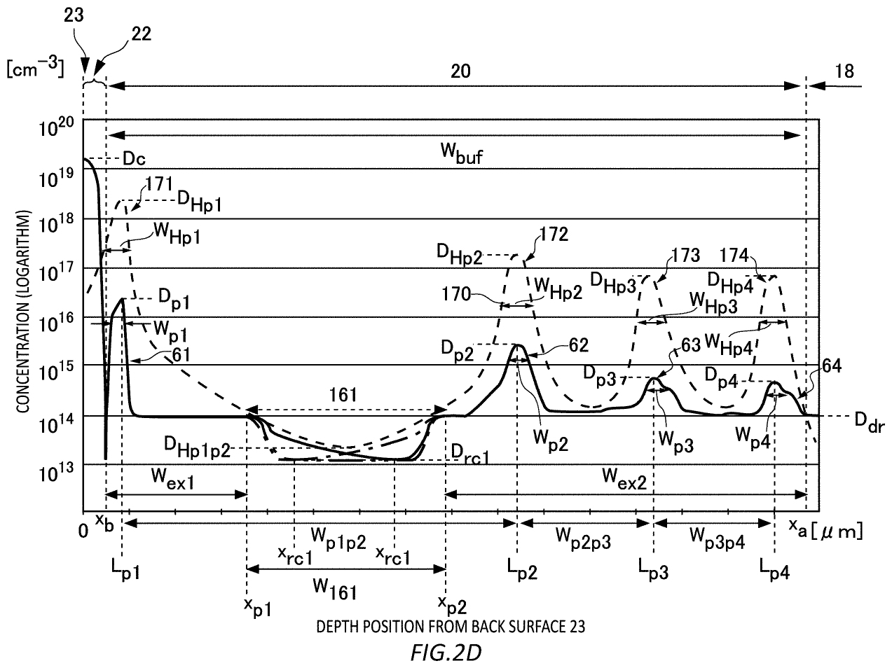

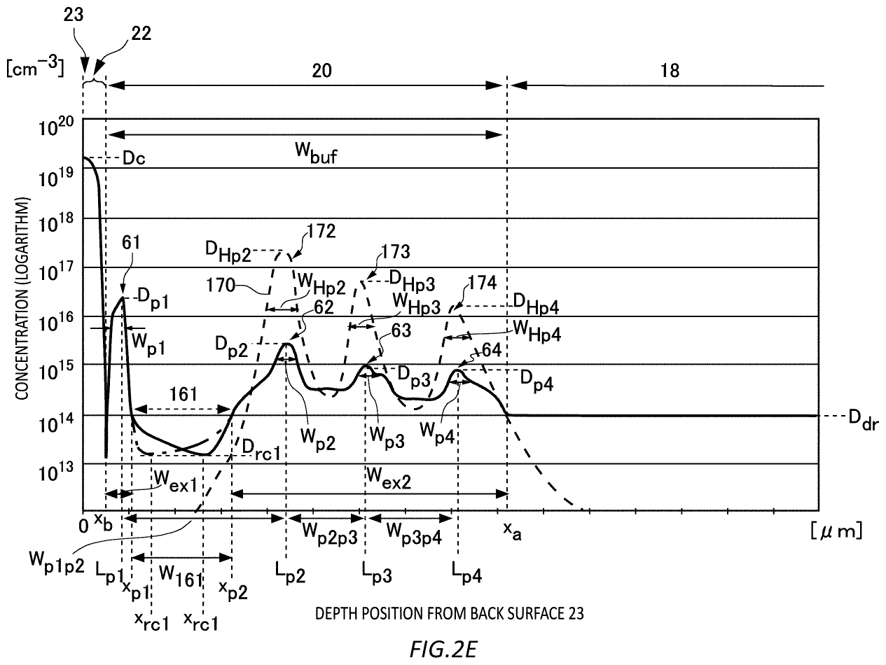

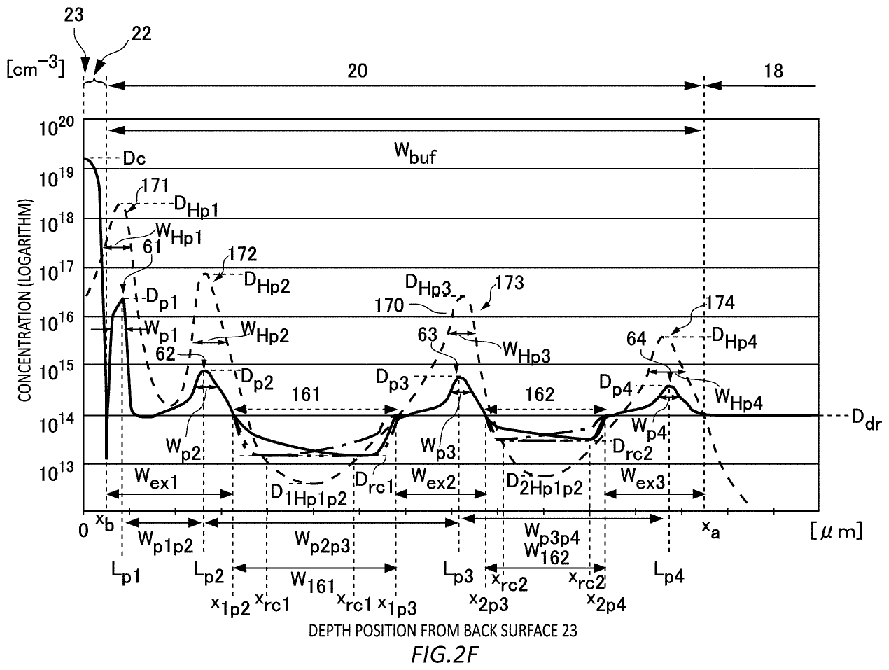

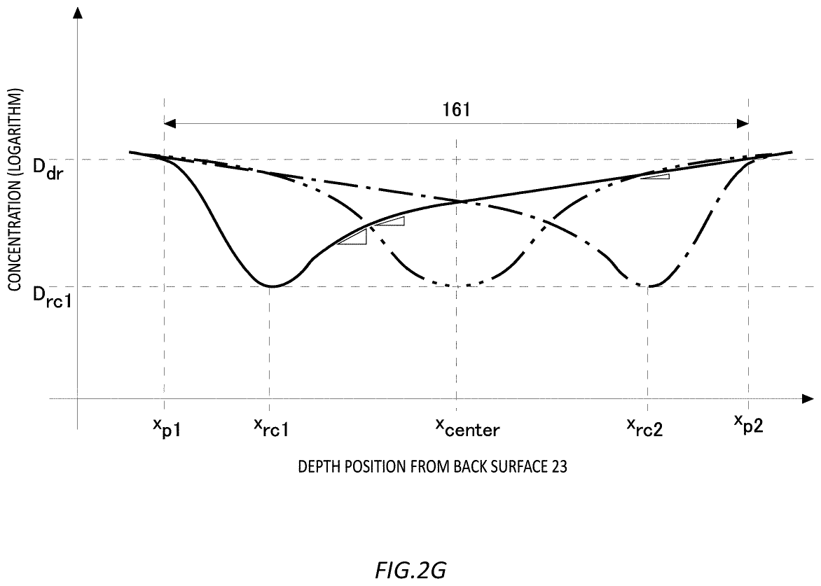

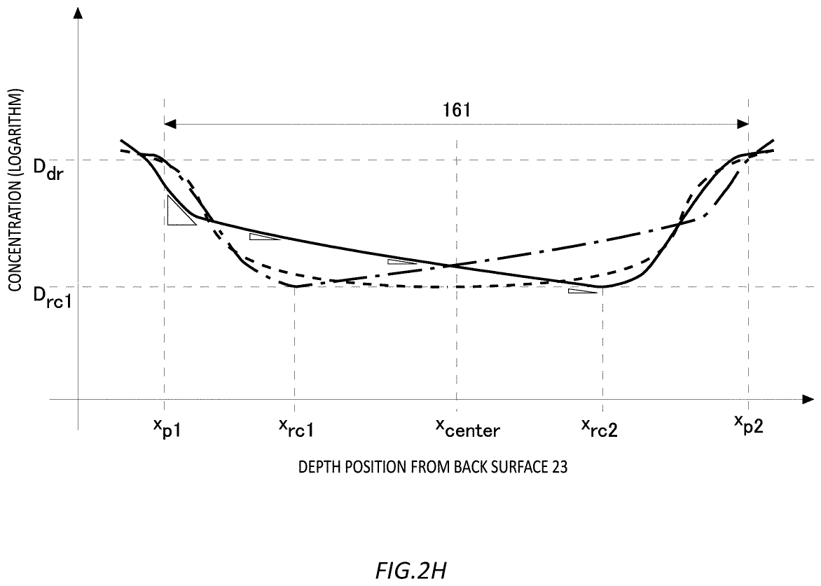

FIG. 2A shows an example of a doping concentration distribution in the collector region 22, the buffer region 20, and the drift region 18. Note that the doping concentration distribution in the collector region 22, the buffer region 20, and the drift region 18 shows a net doping concentration (net doping concentration) as a total of the concentrations of the respective impurities.

A width of the collector region 22 in the depth direction may be 0.2 μm or more and 1.0 μm or less from the back surface 23. A doping concentration Dc at a peak of the collector region 22 may be 1.0 E17 cm⁻³ or more and 1.0 E19 cm⁻³ or less.

The buffer region 20 has a plurality of doping concentrations peaks. The buffer region 20 of the present example has two peaks including a first peak 61 and a second peak 62. A lower end of the buffer region 20 may be a boundary between the collector region 22 and the first peak 61. An upper end of the buffer region 20 may be a boundary between the second peak 62 and the drift region 18. Note that in the present specification, each of the peak positions is a position at which the doping concentration shows a local maximum value. A width of the buffer region 20 in the depth direction may be 5.0 μm or more and 50.0 μm or less.

A boundary position xₐ between the buffer region 20 and the drift region 18 may be a depth position at which the doping concentration of the buffer region 20 becomes equal to the doping concentration D_{dr} of the drift region 18 in the front surface 21 side of the buffer region 20. Alternatively, the boundary position xₐ between the buffer region 20 and the drift region 18 may be a depth position at which the doping concentration of the buffer region 20 becomes equal to the bulk donor concentration in the front surface 21 side of the buffer region 20.

A boundary position x_{b} between the buffer region 20 and the collector region 22 may be a depth position of a PN junction at which the net doping concentration becomes substantially 0. In the case of the diode portion 80, the boundary position x_{b} may be a boundary position between the buffer region 20 and the cathode region 82.

The first peak 61 is provided in the front surface 21 side relative to the collector region 22. The first peak 61 is a peak closest to the back surface 23 out of a plurality of peaks included in the buffer region 20. The first peak 61 may be a peak having a highest doping concentration in the buffer region 20. A dopant of the first peak 61 may be phosphorus, arsenic, or hydrogen. In the present example, the dopant of the first peak 61 is phosphorus.

A depth position Lₚ₁ indicates a depth position of the first peak 61 from the back surface 23. The depth position Lₚ₁ may be 0.5 μm or more and 3.0 μm or less. The depth position Lₚ₁ is, for example, 0.7 μm.

A peak concentration D_{P1} is a doping concentration of the first peak 61. The peak concentration D_{P1} may be lower than the peak concentration Dc of the doping concentration in the collector region 22. The peak concentration D_{P1} may be determined such that a hole concentration or hole current implanted from the collector region 22 in a state where a gate is ON is adjusted to a predetermined magnitude. The peak concentration D_{P1} may be 1.0 E15 cm⁻³ or more, or may be 1.0 E16 cm⁻³ or more. The peak concentration D_{P1} may be 1.0 E17 cm⁻³ or less, or may be 5.0 E16 cm⁻³ or less. For example, the peak concentration D_{P1} is 2.0 E16 cm⁻³.

The second peak 62 is provided in the front surface 21 side relative to the first peak 61. The second peak 62 is a peak second closest to the back surface 23 after the first peak 61 out of the plurality of peaks included in the buffer region 20. The second peak 62 is an example of a hydrogen peak included in the buffer region 20, and is formed by hydrogen ion implantation from the back surface 23 side. The hydrogen peak is a peak of the doping concentration distribution corresponding to a hydrogen chemical concentration peak of a hydrogen chemical concentration distribution 170. The hydrogen peak may be a peak in the donor concentration distribution of the hydrogen donor. The second peak 62 of the present example corresponds to a hydrogen chemical concentration peak 172.

The hydrogen peak is provided in the front surface 21 side of the semiconductor substrate 10 relative to the first lattice defect region 161. The doping concentration of the hydrogen peak may be 1.0 E14 cm⁻³ or more and 1.0 E16 cm⁻³ or less. A plurality of hydrogen peaks may be provided in the front surface 21 side relative to the first lattice defect region 161. As will be described later, the plurality of hydrogen peaks may function as a field stop layer for stopping the depletion layer expanding from the lower surface side of the base region 14.

A depth position Lₚ₂ indicates a depth position of the second peak 62 from the back surface 23. The depth position Lₚ₂ may be 3.0 μm or more and 50.0 μm or less. The depth position Lₚ₂ is, for example, 10.0 μm.

A peak concentration Dₚ₂ is a doping concentration of the second peak 62. The peak concentration D_{P1} may be larger than the peak concentration Dₚ₂. The peak concentration Dₚ₂ may be 1.0 E14 cm⁻³ or more, or may be 1.0 E15 cm⁻³ or more. The peak concentration Dₚ₂ may be 1.0 E16 cm⁻³ or less, or may be 5.0 E15 cm⁻³ or less. The peak concentration Dₚ₂ of the present example is 5.0 E15 cm⁻³.

The respective peaks of the buffer region 20 may be formed using the same dopant, or may be formed using different dopants. The dopant of all the peaks of the buffer region 20 may be hydrogen. The first peak 61 may be formed by phosphorus ion implantation, and peaks other than that may be formed by ion implantation of hydrogen ions. The hydrogen ion may be a proton, a deuteron, or a triton. In the present example, the hydrogen ion is a proton.

The first lattice defect region 161 is provided between the first peak 61 and the second peak 62 in the depth direction of the semiconductor substrate 10. In FIG. 2A, a range where the first lattice defect region 161 is provided in the depth direction of the semiconductor substrate 10 is indicated by a double-headed arrow. A recombination center density in the back surface 23 side relative to the hydrogen peak may be larger than a recombination center density in the drift region 18 in a side adjacent to the hydrogen peak. In the present example, the recombination center density in the back surface 23 side relative to the second peak 62 is larger than the recombination center density in the drift region 18 in a side adjacent to the second peak 62. The first lattice defect region 161 of the present example is a region having a lower doping concentration than the drift region 18. The first lattice defect region 161 may be a region where the doping concentration is lower than the bulk donor concentration. The bulk donor concentration may be lower than the doping concentration of the drift region. In the present example, the bulk donor concentration is equal to the doping concentration of the drift region.

The reason why the doping concentration of the first lattice defect region 161 is lower than that of the drift region 18 is as follows. The first lattice defect region 161 has a higher lattice defect concentration than the drift region 18 in the side adjacent to the second peak 62. Consequently, in the first lattice defect region 161, carriers are easily scattered, and carrier mobility is lower than that of the drift region 18. In the SR measurement, a spreading resistance is measured, and the doping concentration is calculated using the carrier mobility. The carrier mobility used in this calculation is carrier mobility in an ideal crystalline state. However, since the actual carrier mobility in the first lattice defect region 161 is lowered, the doping concentration is calculated that much lower. That is, the doping concentration of the first lattice defect region 161 seemingly falls. Thus, the doping concentration distribution of the first lattice defect region 161 becomes a distribution lower than the doping concentration D_{dr} of the drift region 18 in the side adjacent to the second peak 62. The actual doping concentration of the first lattice defect region 161 has not actually fallen than in such seeming fall and may be considered to be substantially equal to that of the drift region 18.

The doping concentration distribution of the first lattice defect region 161 has a minimum value D_{rc1} of the doping concentration at a depth position x_{rc1}. The depth position x_{rc1} may be positioned in the front surface 21 side (solid line) or the back surface 23 side (dashed-dotted line) relative to an intermediate position of the first lattice defect region 161. The minimum value D_{rc1} of the doping concentration may be higher than or lower than 10% of the doping concentration D_{dr} of the drift region 18. In the present example, the minimum value D_{rc1} of the doping concentration is higher than 10% of the doping concentration D_{dr} of the drift region 18.

The first lattice defect region 161 is provided in the front surface side of the semiconductor substrate 10 relative to the first peak 61 in the depth direction of the semiconductor substrate 10. Further, the second peak 62 of the present example is provided in the front surface 21 side relative to the first lattice defect region 161. Accordingly, an increase in leakage current can be suppressed.

The first lattice defect region 161 of the present example is formed in a passed-through region of hydrogen ions for forming the second peak 62. By the hydrogen ions colliding with atoms of a semiconductor (silicon in the present example) while passing through the semiconductor substrate 10, energy is caused to decay and a crystal lattice is damaged, with the result that many lattice defects are formed in a region shallower than a range Rp of the hydrogen ions (the passed-through region). The lattice defects formed in the passed-through region are each a vacancy-based vacancy-type lattice defect such as a monoatomic vacancy (V) and a divacancy (VV). Atoms adjacent to the vacancies have dangling bonds. The vacancy-type lattice defect becomes a recombination center and promotes recombination of charge carriers. Accordingly, the first lattice defect region 161 is formed in the passed-through region of hydrogen ions.

In the present example, by providing the first lattice defect region 161 such that it extends in the depth direction by the hydrogen ion implantation, a defect density becoming locally higher than that of the first lifetime control region 151 can be avoided. Moreover, the first lattice defect region 161 can be formed by implanting ions deeper and with lower energy than in the first lifetime control region 151. Accordingly, a fall of a short circuit capacity and a vibration during switching can be suppressed.

An interval Wₚ₁ₚ₂ is a distance between the first peak 61 and the second peak 62 in the depth direction of the semiconductor substrate 10. The interval Wₚ₁ₚ₂ may be 5.0 μm or more, or may be 10.0 μm or more. The interval Wₚ₁ₚ₂ may be 20.0 μm or more and 30.0 μm or less. The interval Wₚ₁ₚ₂ may be 40.0 μm or less, or may be 50.0 μm or less. The interval Wₚ₁ₚ₂ may be 5.0 μm or more in the depth direction of the semiconductor substrate 10 and half or less of a thickness of the semiconductor substrate 10 in the depth direction.

A width W₁₆₁ of the first lattice defect region 161 in the depth direction of the semiconductor substrate 10 is defined as follows. A distance from a depth position xₚ₁ at which the doping concentration of the first peak 61 is identical to that of the drift region 18 in the front surface 21 side to a depth position xₚ₂ at which the doping concentration of the second peak 62 is identical to that of the drift region 18 in the back surface 23 side is set as the width W₁₆₁. Note that as described above, the doping concentration D_{dr} of the drift region 18 may be used as the bulk donor concentration. The width W₁₆₁ of the first lattice defect region 161 in the depth direction of the semiconductor substrate 10 may be 25% or more, 50% or more, or 75% or more of the interval Wₚ₁ₚ₂. The width of the first lattice defect region 161 in the depth direction of the semiconductor substrate 10 may be 1.0 μm or more and 10.0 μm or less.

A distance between the depth position x_{rc1} of the first lattice defect region 161 and the depth position xₚ₁ may be larger than (solid line) or smaller than (dashed-dotted line) a distance between the depth position x_{rc1} and the depth position xₚ₂. The doping concentration distribution of the first lattice defect region 161 may have a region where it decreases at substantially a constant gradient from the depth position xₚ₁ toward the depth position x_{rc1}. The doping concentration distribution of the first lattice defect region 161 may have a region where it decreases at substantially a constant gradient from the depth position xₚ₂ toward the depth position x_{rc1}. The gradient being substantially constant may mean that a value of the gradient is within a range of ±50% of an average value of the gradient across 30% to 70% of a range between the depth position xₚ₁ and the depth position x_{rc1} or between the depth position xₚ₂ and the depth position x_{rc1}.

The width W₁₆₁ of the first lattice defect region 161 in the depth direction of the semiconductor substrate 10 may be larger than a width W_{P1} of the first peak 61. The width W₁₆₁ of the first lattice defect region 161 in the depth direction of the semiconductor substrate 10 may be larger than a width W_{P2} of the second peak 62. The width W_{P1} of the first peak 61 and the width W_{P2} of the second peak 62 may each be a full width at half maximum with respect to a local maximum value of the doping concentration (a peak doping concentration) in each peak. The width W_{P1} of the first peak 61 and the width W_{P2} of the second peak 62 may each be a full width at 10% with respect to the local maximum value of the doping concentration (the peak doping concentration) in each peak. The full width at 10% is a width at 0.1 D_{P2} as a concentration that is 10% of the peak concentration D_{P2}.

The width W₁₆₁ of the first lattice defect region 161 in the depth direction of the semiconductor substrate 10 may be larger than a width W_{Hp2} of a peak of the hydrogen chemical concentration of the second peak 62. The width W_{Hp2} of the peak of the hydrogen chemical concentration of the second peak 62 may be a full width at half maximum of the peak concentration D_{Hp2} of the hydrogen chemical concentration of the second peak 62. The width W_{Hp2} of the peak of the hydrogen chemical concentration of the second peak 62 may be a full width at 10% of the peak concentration D_{Hp2} of the hydrogen chemical concentration of the second peak 62. The full width at 10% is a width at 0.1 D_{Hp2} as a concentration that is 10% of the peak concentration D_{Hp2}. Since the hydrogen chemical concentration is higher than the doping concentration, the width W_{Hp2} of the peak of the hydrogen chemical concentration of the second peak 62 can be used to clearly define the width W_{Hp2} of the peak.

The width W₁₆₁ of the first lattice defect region 161 in the depth direction of the semiconductor substrate 10 may be 50% or more of a width W_{buf} of the buffer region 20.

A sum of widths of regions other than the first lattice defect region 161 in the buffer region 20 in the depth direction is represented by W_{EX}. In the example of FIG. 2A, the number of regions other than the first lattice defect region 161 in the buffer region 20 is two. First is a region from the depth position x_{b} to the depth position xₚ₁, and a width thereof in the depth direction is represented by Wₑₓ₁. Second is a region from the depth position xₚ₂ to the depth position xₐ, and a width thereof in the depth direction is represented by Wₑₓ₂. A sum W_{EX} of the widths of the regions other than the first lattice defect region 161 in the depth direction is represented by Wₑₓ1+Wₑₓ₂. The sum W_{EX} of the widths of the regions other than the first lattice defect region 161 in the depth direction is a value obtained by subtracting the width W₁₆₁ of the first lattice defect region 161 in the depth direction from the interval Wₚ₁ₚ₂. The width W₁₆₁ of the first lattice defect region 161 in the depth direction may be larger than the sum W_{EX} of the widths. By increasing the width W₁₆₁ of the first lattice defect region 161 in the depth direction, trade-offs among the turn-off loss, the inter-collector-emitter saturation voltage, and the leakage current can be improved. By increasing the width W₁₆₁ of the first lattice defect region 161 in the depth direction, the turn-off loss can be made small.

The hydrogen chemical concentration in the first lattice defect region 161 may be smaller than the doping concentration D_{dr} of the drift region 18, or may be smaller than the bulk donor concentration. The hydrogen chemical concentration in the first lattice defect region 161 may be smaller than 1×10¹⁵ atoms/cm³, smaller than 5×10¹⁴ atoms/cm³, or smaller than 1×10¹⁴ atoms/cm³. Many lattice defects exist in the first lattice defect region 161. The lattice defects have many dangling bonds that do not contribute to the attachment therein, and forms a recombination center. Therefore, a carrier lifetime in the first lattice defect region 161 is lowered. On the other hand, when hydrogen exists in the first lattice defect region 161, the dangling bonds are terminated by hydrogen. As a result, the recombination center concentration decreases, and lowering of the carrier lifetime in the first lattice defect region 161 is suppressed. In this regard, the hydrogen chemical concentration in the first lattice defect region 161 is set to be smaller than the doping concentration of the drift region, for example. Accordingly, it is possible to suppress the termination of the dangling bonds by hydrogen, cause the recombination center in the first lattice defect region 161 to remain widely, and make the carrier lifetime small. A minimum value of the hydrogen chemical concentration in the first lattice defect region 161 may be smaller than the peak concentration D_{P1} of the first peak 61, may be smaller than the doping concentration of the drift region, or may be smaller than the bulk donor concentration.

The depletion layer in the off state expands toward the back surface 23 in the drift region 18 in the front surface 21 side. The depletion layer may stop at the second peak 62 which is the hydrogen peak. Further, a position at which an integrated concentration reaches a critical integrated concentration may be positioned inside the second peak 62. The critical integrated concentration will be described later. Accordingly, since the depletion layer does not penetrate into the first lattice defect region 161, the leakage current can be prevented from increasing.

FIG. 2B shows a modified example of the semiconductor device 100. The present example differs from the example shown in FIG. 2A in that the first peak 61 is formed by hydrogen ion implantation. A hydrogen chemical concentration peak 171 is a peak of the hydrogen chemical concentration distribution 170 corresponding to the first peak 61. When a dopant of the first peak 61 is hydrogen, the hydrogen chemical concentration increases to a concentration of the same order as the doping concentration D_{dr} of the drift region 18 or the bulk donor concentration at an intermediate portion between the depth position Lp1 and the depth position Lp2. Accordingly, from the vicinity of the first peak 61 to the intermediate portion between the depth position Lp1 and the depth position Lp2, the dangling bonds existing in the lattice defects are terminated by hydrogen, or a concentration of the hydrogen donor increases. Accordingly, defects in the vicinity of the first peak 61 are recovered, and the width of the first lattice defect region 161 in the depth direction of the semiconductor substrate 10 becomes smaller than that in the case of the example shown in FIG. 2A. In this manner, by selectively using the dopant of the first peak 61, the width of the first lattice defect region 161 can be adjusted.

The width W₁₆₁ of the first lattice defect region 161 in the depth direction of the semiconductor substrate 10 may be 25% or more, 50% or more, or 75% or more of the interval Wₚ₁ₚ₂. The width W₁₆₁ of the first lattice defect region 161 in the depth direction of the semiconductor substrate 10 may be 1.0 μm or more and 10.0 μm or less.

A distance between the depth position x_{rc1} of the first lattice defect region 161 and the depth position xₚ₁ may be larger than (solid line) or smaller than (dashed-dotted line) a distance between the depth position x_{rc1} and the depth position xₚ₂. The doping concentration distribution of the first lattice defect region 161 may have a region where it decreases at substantially a constant gradient from the depth position xₚ₁ toward the depth position x_{rc1} (solid line). Alternatively, the doping concentration distribution of the first lattice defect region 161 may have a region where it decreases at substantially a constant gradient from the depth position xₚ₂ toward the depth position x_{rc1} (dashed-dotted line).

The width W₁₆₁ of the first lattice defect region 161 in the depth direction of the semiconductor substrate 10 may be larger than the width W_{P1} of the first peak 61, or may be larger than the width W_{P2} of the second peak 62. The width W_{P1} of the first peak 61 and the width W_{P2} of the second peak 62 may each be a full width at half maximum or a full width at 10% with respect to a local maximum value of the doping concentration (the peak doping concentration) in each peak.

The width W₁₆₁ of the first lattice defect region 161 in the depth direction of the semiconductor substrate 10 may be larger than the width W_{Hp1} of the peak of the hydrogen chemical concentration in the first peak 61, or may be larger than the width W_{Hp2} of the peak of the hydrogen chemical concentration in the second peak 62. The width W_{Hp1} of the peak of the hydrogen chemical concentration in the first peak 61 may be a full width at half maximum or a full width at 10% of the peak concentration D_{Hp1} of the hydrogen chemical concentration in the first peak 61. The width W_{Hp2} of the peak of the hydrogen chemical concentration in the second peak 62 may be a full width at half maximum or a full width at 10% of the peak concentration D_{Hp2} of the hydrogen chemical concentration in the second peak 62.

The width W₁₆₁ of the first lattice defect region 161 in the depth direction of the semiconductor substrate 10 may be 50% or more of a width W_{buf} of the buffer region 20. The width W₁₆₁ of the first lattice defect region 161 in the depth direction may be larger than the sum W_{EX} of the widths of the regions other than the first lattice defect region 161 in the buffer region 20 in the depth direction. By increasing the width W₁₆₁ of the first lattice defect region 161 in the depth direction, trade-offs among the turn-off loss, the inter-collector-emitter saturation voltage, and the leakage current can be improved. By increasing the width W₁₆₁ of the first lattice defect region 161 in the depth direction, the turn-off loss can be made small.

The minimum value D_{Hp1p2} of the hydrogen chemical concentration in the first lattice defect region 161 may be smaller than the peak concentration D_{P1} of the first peak 61, may be smaller than the peak concentration D_{P2} of the second peak 62, may be smaller than the doping concentration D_{dr} of the drift region 18, or may be smaller than the bulk donor concentration. The minimum value D_{Hp1p2} of the hydrogen chemical concentration in the first lattice defect region 161 may be smaller than 5×10¹⁵ atoms/cm³, or may be smaller than 1×10¹⁵ atoms/cm³. The minimum value D_{Hp1p2} of the hydrogen chemical concentration in the first lattice defect region 161 may be larger than 1×10¹² atoms/cm³, or may be larger than 1×10¹³ atoms/cm³. By making the hydrogen chemical concentration in the first lattice defect region 161 small, the lattice defects can be caused to remain widely.

FIG. 2C shows a modified example of the semiconductor device 100. The buffer region 20 of the present example has three peaks including the first peak 61, the second peak 62, and a third peak 63. The buffer region 20 has the first peak 61 and a plurality of hydrogen peaks. The second peak 62 and the third peak 63 are each an example of the hydrogen peak. Note that in the present example, the first peak 61 is also formed by hydrogen ion implantation. A hydrogen chemical concentration peak 171 is a peak of the hydrogen chemical concentration distribution 170 corresponding to the first peak 61. A hydrogen chemical concentration peak 173 is a peak of the hydrogen chemical concentration distribution 170 corresponding to the third peak 63.

The third peak 63 is provided in the front surface 21 side relative to the second peak 62 in the depth direction of the semiconductor substrate 10. A depth position Lₚ₃ indicates a depth position of the third peak 63 from the back surface 23. The depth position Lₚ₃ may be 7.0 μm or more and 13.0 μm or less, and is, for example, 10.0 μm.

A peak concentration Dₚ₃ is a doping concentration of the third peak 63. The peak concentration Dₚ₃ may be smaller than the peak concentration D_{P1} and the peak concentration Dₚ₂. The peak concentration Dₚ₃ may be 1.0 E14 cm⁻³ or more and 1.0 E16 cm⁻³ or less.

The first lattice defect region 161 is provided between the first peak 61 and the second peak 62 in the depth direction of the semiconductor substrate 10, but is not provided between the second peak 62 and the third peak 63. That is, in the present example, an interval Wₚ₂ₚ₃ between the second peak 62 and the third peak 63 is smaller than the interval Wₚ₁ₚ₂ between the first peak 61 and the second peak 62. The hydrogen chemical concentration increases to a concentration of the same order as the doping concentration D_{dr} of the drift region 18 or the bulk donor concentration at an intermediate portion between the depth position Lₚ₂ and the depth position Lₚ₃. Accordingly, defects are recovered between the second peak 62 and the third peak 63, or the concentration of the hydrogen donor increases. By adjusting the interval between the peaks in this manner, it is possible to control whether to form the first lattice defect region 161. The interval Wₚ₂ₚ₃ may be 1.0 μm or more and smaller than 5.0 μm.

The width W₁₆₁ of the first lattice defect region 161 in the depth direction of the semiconductor substrate 10 may be 25% or more, 50% or more, or 75% or more of the interval Wₚ₁ₚ₂. The width W₁₆₁ of the first lattice defect region 161 in the depth direction of the semiconductor substrate 10 may be 1.0 μm or more and 10.0 μm or less.

A distance between the depth position x_{rc1} of the first lattice defect region 161 and the depth position xₚ₁ may be larger than (solid line) or smaller than (dashed-dotted line) a distance between the depth position x_{rc1} and the depth position xₚ₂. The doping concentration distribution of the first lattice defect region 161 may have a region where it decreases at substantially a constant gradient from the depth position xₚ₁ toward the depth position x_{rc1} (solid line). Alternatively, the doping concentration distribution of the first lattice defect region 161 may have a region where it decreases at substantially a constant gradient from the depth position xₚ₂ toward the depth position x_{rc1} (dashed-dotted line).

The doping concentration distribution of the first lattice defect region 161 may have a region where an absolute value of the gradient of the doping concentration increases, a region where it decreases, and a region where the doping concentration is substantially constant (chain double-dashed line) from the position xₚ₁ and the position xₚ₂ at the respective end portions of the first lattice defect region 161 toward a position at which the minimum value D_{rc1} is obtained.

The width W₁₆₁ of the first lattice defect region 161 in the depth direction of the semiconductor substrate 10 may be larger than the width W_{P1} of the first peak 61, may be larger than the width W_{P2} of the second peak 62, or may be larger than the width W_{P3} of the third peak 63. The width W_{P1} of the first peak 61, the width W_{P2} of the second peak 62, and the width W_{P3} of the third peak 63 may each be a full width at half maximum or a full width at 10% with respect to a local maximum value of the doping concentration (the peak doping concentration) in each peak.

The width W₁₆₁ of the first lattice defect region 161 in the depth direction of the semiconductor substrate 10 may be larger than the width W_{Hp1} of the peak of the hydrogen chemical concentration in the first peak 61, may be larger than the width W_{Hp2} of the peak of the hydrogen chemical concentration in the second peak 62, or may be larger than the width W_{Hp3} of the peak of the hydrogen chemical concentration in the third peak 63. The width W_{Hp1} of the peak of the hydrogen chemical concentration in the first peak 61 may be a full width at half maximum or a full width at 10% with respect to the peak concentration D_{Hp1} of the hydrogen chemical concentration in the first peak 61. The width W_{Hp2} of the peak of the hydrogen chemical concentration in the second peak 62 may be a full width at half maximum or a full width at 10% with respect to the peak concentration D_{Hp2} of the hydrogen chemical concentration in the second peak 62. The width W_{Hp3} of the peak of the hydrogen chemical concentration in the third peak 63 may be a full width at half maximum or a full width at 10% with respect to the peak concentration D_{Hp3} of the hydrogen chemical concentration in the third peak 63.

The width W₁₆₁ of the first lattice defect region 161 in the depth direction of the semiconductor substrate 10 may be 50% or more of a width W_{buf} of the buffer region 20. The width W₁₆₁ of the first lattice defect region 161 in the depth direction may be larger than the sum W_{EX} of the widths of the regions other than the first lattice defect region 161 in the buffer region 20 in the depth direction. By increasing the width W₁₆₁ of the first lattice defect region 161 in the depth direction, trade-offs among the turn-off loss, the inter-collector-emitter saturation voltage, and the leakage current can be improved. By increasing the width W₁₆₁ of the first lattice defect region 161 in the depth direction, the turn-off loss can be made small.

The minimum value D_{Hp1p2} of the hydrogen chemical concentration in the first lattice defect region 161 may be smaller than the peak concentration D_{P1} of the first peak 61, may be smaller than the peak concentration D_{P2} of the second peak 62, may be smaller than the peak concentration D_{P3} of the third peak 63, may be smaller than the doping concentration D_{dr} of the drift region 18, or may be smaller than the bulk donor concentration. The minimum value D_{Hp1p2} of the hydrogen chemical concentration in the first lattice defect region 161 may be smaller than 5×10¹⁴ atoms/cm³, or may be smaller than 1×10¹⁴ atoms/cm³. The minimum value D_{Hp1p2} of the hydrogen chemical concentration in the first lattice defect region 161 may be larger than 1×10¹² atoms/cm³, or may be larger than 1×10¹³ atoms/cm³. By making the hydrogen chemical concentration in the first lattice defect region 161 small, the lattice defects can be caused to remain widely.

The depletion layer in the off state may extend to the second peak 62 which is the hydrogen peak, or extend to the front surface 21 side relative to the second peak 62. A position at which the integrated concentration reaches the critical integrated concentration may be positioned inside the second peak 62. Accordingly, since the depletion layer does not penetrate into the first lattice defect region 161, the leakage current can be prevented from increasing.

FIG. 2D shows a modified example of the semiconductor device 100. The buffer region 20 of the present example has four peaks including the first peak 61, the second peak 62, the third peak 63, and a fourth peak 64. The buffer region 20 has the first peak 61 and a plurality of hydrogen peaks. The second peak 62, the third peak 63, and the fourth peak 64 are each an example of the hydrogen peak. Note that in the present example, the first peak 61 is also formed by hydrogen ion implantation. The hydrogen chemical concentration peak 171, the hydrogen chemical concentration peak 172, the hydrogen chemical concentration peak 173, and a hydrogen chemical concentration peak 174 respectively correspond to the first peak 61, the second peak 62, the third peak 63, and the fourth peak 64.

The fourth peak 64 is provided in the front surface 21 side relative to the third peak 63 in the depth direction of the semiconductor substrate 10. A depth position Lₚ₄ indicates a depth position of the fourth peak 64 from the back surface 23. The depth position Lₚ₄ may be 10% or more and 20% or less of the substrate thickness of the semiconductor substrate 10. For example, the depth position Lₚ₄ is 15.0 μm.

A peak concentration D_{P4} is a doping concentration of the fourth peak 64. The peak concentration D_{P4} may be smaller than the peak concentration Dp₁, the peak concentration Dₚ₂, and the peak concentration Dₚ₃. The peak concentration D_{P4} may be 1.0 E14 cm⁻³ or more and 1.0 E16 cm⁻³ or less.

The doping concentrations of the four peaks included in the buffer region 20 may gradually decrease toward the front surface 21 side of the semiconductor substrate 10. That is, the peak concentration Dₚ₂ of the second peak 62 may be smaller than the peak concentration Dp₁ of the first peak 61. The peak concentration Dₚ₃ of the third peak 63 may be smaller than the peak concentration Dₚ₂ of the second peak 62. The peak concentration D_{P4} of the fourth peak 64 may be smaller than the peak concentration Dₚ₃ of the third peak 63.

The interval Wₚ₂ₚ₃ between the second peak 62 and the third peak 63 may be smaller than the interval Wₚ₁ₚ₂ between the first peak 61 and the second peak 62. An interval Wₚ₃ₚ₄ between the third peak 63 and the fourth peak 64 may be smaller than the interval Wₚ₁ₚ₂ between the first peak 61 and the second peak 62. Moreover, the interval Wₚ₃ₚ₄ between the third peak 63 and the fourth peak 64 may be the same as or may be different from the interval Wₚ₂ₚ₃ between the second peak 62 and the third peak 63. The interval Wₚ₃ₚ₄ between the third peak 63 and the fourth peak 64 in the present example is smaller than the interval Wₚ₂ₚ₃ between the second peak 62 and the third peak 63.

The first lattice defect region 161 is provided between the first peak 61 and the second peak 62 in the depth direction of the semiconductor substrate 10. The first lattice defect region 161 is not provided between the second peak 62 and the third peak 63 and between the third peak 63 and the fourth peak 64. That is, in the present example, an interval Wₚ₂ₚ₃ between the second peak 62 and the third peak 63 is smaller than the interval Wₚ₁ₚ₂ between the first peak 61 and the second peak 62. The hydrogen chemical concentration increases to a concentration of the same order as the doping concentration D_{dr} of the drift region 18 or the bulk donor concentration at an intermediate portion between the depth position Lₚ₂ and the depth position Lₚ₃. Accordingly, defects are recovered between the second peak 62 and the third peak 63. Further, the interval Wₚ₃ₚ₄ between the third peak 63 and the fourth peak 64 is smaller than the interval Wₚ₁ₚ₂ between the first peak 61 and the second peak 62. The hydrogen chemical concentration increases to a concentration of the same order as the doping concentration D_{dr} of the drift region 18 or the bulk donor concentration at an intermediate portion between the depth position Lₚ₃ and the depth position Lₚ₄. Accordingly, defects are recovered between the third peak 63 and the fourth peak 64. The interval Wₚ₃ₚ₄ may be 1.0 μm or more and smaller than 5.0 μm.

The width W₁₆₁ of the first lattice defect region 161 in the depth direction of the semiconductor substrate 10 may be 25% or more, 50% or more, or 75% or more of the interval Wₚ₁ₚ₂. The width W₁₆₁ of the first lattice defect region 161 in the depth direction of the semiconductor substrate 10 may be 1.0 μm or more and 10.0 μm or less.

A distance between the depth position x_{rc1} of the first lattice defect region 161 and the depth position xₚ₁ may be larger than (solid line) or smaller than (dashed-dotted line) a distance between the depth position x_{rc1} and the depth position xₚ₂. The doping concentration distribution of the first lattice defect region 161 may have a region where it decreases at substantially a constant gradient from the depth position xₚ₁ toward the depth position x_{rc1} (solid line). Alternatively, the doping concentration distribution of the first lattice defect region 161 may have a region where it decreases at substantially a constant gradient from the depth position xₚ₂ toward the depth position x_{rc1} (dashed-dotted line).

The doping concentration distribution of the first lattice defect region 161 may have a region where an absolute value of the gradient of the doping concentration increases, a region where it decreases, and a region where the doping concentration is substantially constant (chain double-dashed line) from the position xₚ₁ and the position xₚ₂ at the respective end portions of the first lattice defect region 161 toward a position at which the minimum value D_{rc1} is obtained.

The width W₁₆₁ of the first lattice defect region 161 in the depth direction of the semiconductor substrate 10 may be larger than the width W_{P1} of the first peak 61, may be larger than the width W_{P2} of the second peak 62, may be larger than the width W_{P3} of the third peak 63, or may be larger than the width W_{P4} of the fourth peak 64. The width W_{P1} of the first peak 61, the width W_{P2} of the second peak 62, the width W_{P3} of the third peak 63, and the width W_{P4} of the fourth peak 64 may each be a full width at half maximum or a full width at 10% with respect to a local maximum value of the doping concentration (the peak doping concentration) in each peak.

The width W₁₆₁ of the first lattice defect region 161 in the depth direction of the semiconductor substrate 10 may be larger than the width W_{Hp1} of the peak of the hydrogen chemical concentration in the first peak 61, may be larger than the width W_{Hp2} of the peak of the hydrogen chemical concentration in the second peak 62, may be larger than the width W_{Hp3} of the peak of the hydrogen chemical concentration in the third peak 63, or may be larger than the width W_{Hp4} of the peak of the hydrogen chemical concentration in the fourth peak 64. The width W_{Hp1} of the peak of the hydrogen chemical concentration in the first peak 61 may be a full width at half maximum or a full width at 10% with respect to the peak concentration D_{Hp1} of the hydrogen chemical concentration in the first peak 61. The width W_{Hp2} of the peak of the hydrogen chemical concentration in the second peak 62 may be a full width at half maximum or a full width at 10% with respect to the peak concentration D_{Hp2} of the hydrogen chemical concentration in the second peak 62. The width W_{Hp3} of the peak of the hydrogen chemical concentration in the third peak 63 may be a full width at half maximum or a full width at 10% with respect to the peak concentration D_{Hp3} of the hydrogen chemical concentration in the third peak 63. The width W_{Hp4} of the peak of the hydrogen chemical concentration in the fourth peak 64 may be a full width at half maximum or a full width at 10% with respect to the peak concentration D_{Hp4} of the hydrogen chemical concentration in the fourth peak 64.

The width Wii of the first lattice defect region 161 in the depth direction of the semiconductor substrate 10 may be 50% or more of a width W_{buf} of the buffer region 20. The width W₁₆₁ of the first lattice defect region 161 in the depth direction may be larger than the sum W_{EX} of the widths of the regions other than the first lattice defect region 161 in the buffer region 20 in the depth direction. By increasing the width W₁₆₁ of the first lattice defect region 161 in the depth direction, trade-offs among the turn-off loss, the inter-collector-emitter saturation voltage, and the leakage current can be improved. By increasing the width W₁₆₁ of the first lattice defect region 161 in the depth direction, the turn-off loss can be made small.

The minimum value D_{Hp1p2} of the hydrogen chemical concentration in the first lattice defect region 161 may be smaller than the peak concentration D_{P1} of the first peak 61, may be smaller than the peak concentration D_{P2} of the second peak 62, may be smaller than the peak concentration D_{P3} of the third peak 63, may be smaller than the peak concentration D_{P4} of the fourth peak 64, may be smaller than the doping concentration D_{dr} of the drift region 18, or may be smaller than the bulk donor concentration. The minimum value D_{Hp1p2} of the hydrogen chemical concentration in the first lattice defect region 161 may be smaller than 5×10¹⁵ atoms/cm³, or may be smaller than 1×10¹⁵ atoms/cm³. The minimum value D_{Hp1p2} of the hydrogen chemical concentration in the first lattice defect region 161 may be larger than 1×10¹² atoms/cm³, or may be larger than 1×10¹³ atoms/cm³. By making the hydrogen chemical concentration in the first lattice defect region 161 small, the lattice defects can be caused to remain widely.

FIG. 2E shows a modified example of the semiconductor device 100. The present example differs from the example shown in FIG. 2D in that the interval Wₚ₁ₚ₂ between the first peak 61 and the second peak 62 is smaller than the interval Wₚ₁ₚ₂ in the example shown in FIG. 2D and that the first peak 61 is formed by phosphorus ion implantation. When the dopant of the first peak 61 is phosphorus, defects have not recovered in the vicinity of the first peak 61, and the distance between the first peak 61 and the first lattice defect region 161 is smaller than that in the case of the example shown in FIG. 2D.

The interval Wₚ₁ₚ₂ between the first peak 61 and the second peak 62 in the present example is smaller than the interval Wₚ₁ₚ₂ in the example shown in FIG. 2D. By forming the first peak 61 using phosphorus in this manner, even when the interval Wₚ₁ₚ₂ is made small, the first lattice defect region 161 can be formed between the first peak 61 and the second peak 62. The interval Wₚ₁ₚ₂ may be 2.0 μm or more, or may be 3.0 μm or more. The interval Wₚ₁ₚ₂ may be smaller than 10.0 μm, or may be smaller than 5.0 μm.

The width W₁₆₁ of the first lattice defect region 161 in the depth direction of the semiconductor substrate 10 may be 25% or more, 50% or more, or 75% or more of the interval Wₚ₁ₚ₂.

A distance between the depth position x_{rc1} of the first lattice defect region 161 and the depth position xₚ₁ may be larger than (solid line) or smaller than (dashed-dotted line) a distance between the depth position x_{rc1} and the depth position xₚ₂. The doping concentration distribution of the first lattice defect region 161 may have a region where it decreases at substantially a constant gradient from the depth position xₚ₁ toward the depth position x_{rc1} (solid line). Alternatively, the doping concentration distribution of the first lattice defect region 161 may have a region where it decreases at substantially a constant gradient from the depth position xₚ₂ toward the depth position x_{rc1} (dashed-dotted line).

The width W₁₆₁ of the first lattice defect region 161 in the depth direction of the semiconductor substrate 10 may be larger than the width W_{P1} of the first peak 61, may be larger than the width W_{P2} of the second peak 62, may be larger than the width W_{P3} of the third peak 63, or may be larger than the width W_{P4} of the fourth peak 64. The width W_{P1} of the first peak 61, the width W_{P2} of the second peak 62, the width W_{P3} of the third peak 63, and the width W_{P4} of the fourth peak 64 may each be a full width at half maximum or a full width at 10% with respect to a local maximum value of the doping concentration (the peak doping concentration) in each peak.

The width W₁₆₁ of the first lattice defect region 161 in the depth direction of the semiconductor substrate 10 may be larger than the width W_{Hp2} of the peak of the hydrogen chemical concentration in the second peak 62, may be larger than the width W_{Hp3} of the peak of the hydrogen chemical concentration in the third peak 63, or may be larger than the width W_{Hp4} of the peak of the hydrogen chemical concentration in the fourth peak 64. The width W_{Hp2} of the peak of the hydrogen chemical concentration in the second peak 62 may be a full width at half maximum or a full width at 10% with respect to the peak concentration D_{Hp2} of the hydrogen chemical concentration in the second peak 62. The width W_{Hp3} of the peak of the hydrogen chemical concentration in the third peak 63 may be a full width at half maximum or a full width at 10% with respect to the peak concentration D_{Hp3} of the hydrogen chemical concentration in the third peak 63. The width W_{Hp4} of the peak of the hydrogen chemical concentration in the fourth peak 64 may be a full width at half maximum or a full width at 10% with respect to the peak concentration D_{Hp4} of the hydrogen chemical concentration in the fourth peak 64.

The width W₁₆₁ of the first lattice defect region 161 in the depth direction of the semiconductor substrate 10 may be 50% or more of a width W_{buf} of the buffer region 20. The width W₁₆₁ of the first lattice defect region 161 in the depth direction may be larger than the sum W_{EX} of the widths of the regions other than the first lattice defect region 161 in the buffer region 20 in the depth direction. By increasing the width W₁₆₁ of the first lattice defect region 161 in the depth direction, trade-offs among the turn-off loss, the inter-collector-emitter saturation voltage, and the leakage current can be improved. By increasing the width W₁₆₁ of the first lattice defect region 161 in the depth direction, the turn-off loss can be made small.

The minimum value of the hydrogen chemical concentration in the first lattice defect region 161 may be smaller than the peak concentration D_{P1} of the first peak 61, may be smaller than the peak concentration D_{P2} of the second peak 62, may be smaller than the peak concentration D_{P3} of the third peak 63, may be smaller than the peak concentration D_{P4} of the fourth peak 64, may be smaller than the doping concentration D_{dr} of the drift region 18, or may be smaller than the bulk donor concentration. The hydrogen chemical concentration in the first lattice defect region 161 may be smaller than 1×10¹⁵ atoms/cm³, smaller than 5×10¹⁴ atoms/cm³, or smaller than 1×10¹⁴ atoms/cm³. By making the hydrogen chemical concentration in the first lattice defect region 161 small, the lattice defects can be caused to remain widely.

FIG. 2F shows a modified example of the semiconductor device 100. The buffer region 20 of the present example has two lattice defect regions including the first lattice defect region 161 and a second lattice defect region 162. The buffer region 20 of the present example has four peaks including the first peak 61, the second peak 62, the third peak 63, and a fourth peak 64. The first peak 61 of the present example is formed by hydrogen ion implantation.

The first lattice defect region 161 is provided between the plurality of hydrogen peaks in the depth direction of the semiconductor substrate 10. The first lattice defect region 161 of the present example is provided between the second peak 62 and the third peak 63. The interval Wₚ₂ₚ₃ between the second peak 62 and the third peak 63 may be larger than the interval Wₚ₁ₚ₂ between the first peak 61 and the second peak 62. The interval Wₚ₂ₚ₃ may be 3.0 μm or more, or may be 5.0 μm or more. The interval Wₚ₂ₚ₃ may be smaller than 10.0 μm, or may be smaller than 7.0 μm.

The doping concentration distribution of the first lattice defect region 161 has a minimum value D_{rc1} of the doping concentration at a depth position x_{rc1}. The depth position x_{rc1} may be positioned in the front surface 21 side (solid line) or the back surface side (dashed-dotted line) relative to an intermediate position of the first lattice defect region 161. The minimum value D_{rc1} of the doping concentration may be higher than or lower than 10% of the doping concentration D_{dr} of the drift region 18. In the present example, the minimum value D_{rc1} of the doping concentration is higher than 10% of the doping concentration D_{dr} of the drift region 18.

The width W₁₆₁ of the first lattice defect region 161 in the depth direction of the semiconductor substrate 10 may be 25% or more, 50% or more, or 75% or more of the interval Wₚ₁ₚ₂. The width W₁₆₁ of the first lattice defect region 161 in the depth direction of the semiconductor substrate 10 may be 1.0 μm or more and 10.0 μm or less.

A distance between the depth position x_{rc1} of the first lattice defect region 161 and a depth position x₁ₚ₂ may be larger than (solid line) or smaller than (dashed-dotted line) a distance between the depth position x_{rc1} and a depth position x₁ₚ₃. The doping concentration distribution of the first lattice defect region 161 may have a region where it decreases at substantially a constant gradient from the depth position x₁ₚ₂ toward the depth position x_{rc1} (solid line). Alternatively, the doping concentration distribution of the first lattice defect region 161 may have a region where it decreases at substantially a constant gradient from the depth position x₁ₚ₃ toward the depth position x_{rc1} (dashed-dotted line).

The doping concentration distribution of the first lattice defect region 161 may have a region where an absolute value of the gradient of the doping concentration increases, a region where it decreases, and a region where the doping concentration is substantially constant (chain double-dashed line) from the position x₁ₚ₂ and the position x₁ₚ₃ at the respective end portions of the first lattice defect region 161 toward a position at which the minimum value D_{rc1} is obtained.

The distance between the depth position x_{rc1} of the first lattice defect region 161 and the depth position x₁ₚ₂ may be larger than (solid line) or smaller than (dashed-dotted line) the distance between the depth position x_{rc1} and the depth position x₁ₚ₃. The doping concentration distribution of the first lattice defect region 161 may have a region where it decreases at substantially a constant gradient from the depth position x₁ₚ₂ toward the depth position x_{rc1}. The doping concentration distribution of the first lattice defect region 161 may have a region where it decreases at substantially a constant gradient from the depth position x₁ₚ₃ toward the depth position x_{rc1}. The gradient being substantially constant may mean that a value of the gradient is within a range of 50% of an average value of the gradient across 30% to 70% of a range between the depth position x₁ₚ₂ and the depth position x_{rc1} or between the depth position x₁ₚ₃ and the depth position x_{rc1}.

The width W₁₆₁ of the first lattice defect region 161 in the depth direction of the semiconductor substrate 10 may be larger than the width W_{P1} of the first peak 61, may be larger than the width W_{P2} of the second peak 62, may be larger than the width W_{P3} of the third peak 63, or may be larger than the width W_{P4} of the fourth peak 64. The width W_{P1} of the first peak 61, the width W_{P2} of the second peak 62, the width W_{P3} of the third peak 63, and the width W_{P4} of the fourth peak 64 may each be a full width at half maximum or a full width at 10% with respect to a local maximum value of the doping concentration (the peak doping concentration) in each peak.

The width W₁₆₁ of the first lattice defect region 161 in the depth direction of the semiconductor substrate 10 may be larger than the width W_{Hp1} of the peak of the hydrogen chemical concentration in the first peak 61, may be larger than the width W_{Hp2} of the peak of the hydrogen chemical concentration in the second peak 62, may be larger than the width W_{Hp3} of the peak of the hydrogen chemical concentration in the third peak 63, or may be larger than the width W_{Hp4} of the peak of the hydrogen chemical concentration in the fourth peak 64. The width W_{Hp1} of the peak of the hydrogen chemical concentration in the first peak 61 may be a full width at half maximum or a full width at 10% with respect to the peak concentration D_{Hp1} of the hydrogen chemical concentration in the first peak 61. The width W_{Hp2} of the peak of the hydrogen chemical concentration in the second peak 62 may be a full width at half maximum or a full width at 10% with respect to the peak concentration D_{Hp2} of the hydrogen chemical concentration in the second peak 62. The width W_{Hp3} of the peak of the hydrogen chemical concentration in the third peak 63 may be a full width at half maximum or a full width at 10% with respect to the peak concentration D_{Hp3} of the hydrogen chemical concentration in the third peak 63. The width W_{Hp4} of the peak of the hydrogen chemical concentration in the fourth peak 64 may be a full width at half maximum or a full width at 10% with respect to the peak concentration D_{Hp4} of the hydrogen chemical concentration in the fourth peak 64.

The width W₁₆₁ of the first lattice defect region 161 in the depth direction of the semiconductor substrate 10 may be 50% or more of a width W_{buf} of the buffer region 20. The width W₁₆₁ of the first lattice defect region 161 in the depth direction may be larger than the sum W_{EX} of the widths of the regions other than the first lattice defect region 161 in the buffer region 20 in the depth direction. By increasing the width W₁₆₁ of the first lattice defect region 161 in the depth direction, trade-offs among the turn-off loss, the inter-collector-emitter saturation voltage, and the leakage current can be improved. By increasing the width W₁₆₁ of the first lattice defect region 161 in the depth direction, the turn-off loss can be made small.

The minimum value D_{1Hp1p2} of the hydrogen chemical concentration in the first lattice defect region 161 may be smaller than the peak concentration D_{P1} of the first peak 61, may be smaller than the peak concentration D_{P2} of the second peak 62, may be smaller than the peak concentration D_{P3} of the third peak 63, may be smaller than the peak concentration D_{P4} of the fourth peak 64, may be smaller than the doping concentration D_{dr} of the drift region 18, or may be smaller than the bulk donor concentration. The minimum value D_{1Hp1p2} of the hydrogen chemical concentration in the first lattice defect region 161 may be smaller than 5×10¹⁴ atoms/cm³, or may be smaller than 1×10¹⁴ atoms/cm³. The minimum value D_{1Hp1p2} of the hydrogen chemical concentration in the first lattice defect region 161 may be larger than 1×10¹² atoms/cm³, or may be larger than 1×10¹³ atoms/cm³. By making the hydrogen chemical concentration in the first lattice defect region 161 small, the lattice defects can be caused to remain widely.

The second lattice defect region 162 is a lattice defect region that is provided in the buffer region 20 and is different from the first lattice defect region 161. Similar to the first lattice defect region 161, the second lattice defect region 162 is formed in the passed-through region of hydrogen ions during implantation of hydrogen ions. The second lattice defect region 162 is provided between the plurality of hydrogen peaks in the front surface 21 side of the semiconductor substrate 10 relative to the first lattice defect region 161 in the depth direction of the semiconductor substrate 10. The second lattice defect region 162 of the present example is provided between the third peak 63 and the fourth peak 64. The interval Wₚ₃ₚ₄ between the third peak 63 and the fourth peak 64 may be larger than the interval Wₚ₁ₚ₂ between the first peak 61 and the second peak 62. Moreover, the interval Wₚ₃ₚ₄ between the third peak 63 and the fourth peak 64 may be the same as the interval Wₚ₂ₚ₃ between the second peak 62 and the third peak 63, or may be smaller than the interval Wₚ₂ₚ₃. The interval Wₚ₃ₚ₄ may be 3.0 μm or more, or may be 5.0 μm or more. The interval Wₚ₃ₚ₄ may be smaller than 10.0 μm, or may be smaller than 7.0 μm.

Similar to the first lattice defect region 161, the doping concentration distribution of the second lattice defect region 162 has a minimum value D_{rc2} of the doping concentration at the depth position x_{rc2}. The depth position x_{rc2} may be positioned in the front surface 21 side (solid line) or the back surface 23 side (dashed-dotted line) relative to an intermediate position of the second lattice defect region 162. The minimum value D_{rc2} of the doping concentration may be higher than or lower than 10% of the doping concentration D_{dr} of the drift region 18. In the present example, the minimum value D_{rc2} of the doping concentration is higher than 10% of the doping concentration D_{dr} of the drift region 18. The minimum value D_{rc2} of the doping concentration may be higher than or lower than the minimum value D_{rc1} of the doping concentration of the first lattice defect region 161 as in the present example.

A width W₁₆₂ of the second lattice defect region 162 in the depth direction of the semiconductor substrate 10 may be 25% or more, 50% or more, or 75% or more of the interval Wₚ₃ₚ₄. The width W₁₆₂ of the second lattice defect region 162 in the depth direction of the semiconductor substrate 10 may be 1.0 μm or more and 10.0 μm or less.

A distance between the depth position x_{rc2} of the second lattice defect region 162 and a depth position x₂ₚ₃ may be larger than (solid line) or smaller than (dashed-dotted line) a distance between the depth position x_{rc2} and a depth position x₂ₚ₄. The doping concentration distribution of the second lattice defect region 162 may have a region where it decreases at substantially a constant gradient from the depth position x₂ₚ₃ toward the depth position x_{rc2} (solid line). Alternatively, the doping concentration distribution of the second lattice defect region 162 may have a region where it decreases at substantially a constant gradient from the depth position x₂ₚ₄ toward the depth position x_{rc2} (dashed-dotted line).

The doping concentration distribution of the second lattice defect region 162 may have a region where an absolute value of the gradient of the doping concentration increases, a region where it decreases, and a region where the doping concentration is substantially constant (chain double-dashed line) from the position x₂ₚ₃ and the position x₂ₚ₄ at the respective end portions of the second lattice defect region 162 toward a position at which the minimum value D_{rc2} is obtained.

A distance between the depth position x_{rc2} of the second lattice defect region 162 and a depth position x₂ₚ₃ may be larger than (solid line) or smaller than (dashed-dotted line) a distance between the depth position x_{rc2} and a depth position x₂ₚ₄. The doping concentration distribution of the second lattice defect region 162 may have a region where it decreases at substantially a constant gradient from the depth position x₂ₚ₃ toward the depth position x_{rc2}. The doping concentration distribution of the second lattice defect region 162 may have a region where it decreases at substantially a constant gradient from the depth position x₂ₚ₄ toward the depth position x_{rc2}. The gradient being substantially constant may mean that a value of the gradient is within a range of 50% of an average value of the gradient across 30% to 70% of a range between the depth position x₂ₚ₃ and the depth position x_{rc2} or between the depth position x₂ₚ₄ and the depth position x_{rc2}.

The width W₁₆₂ of the second lattice defect region 162 in the depth direction of the semiconductor substrate 10 may be larger than the width W_{P1} of the first peak 61, may be larger than the width W_{P2} of the second peak 62, may be larger than the width W_{P3} of the third peak 63, or may be larger than the width W_{P4} of the fourth peak 64. The width W_{P1} of the first peak 61, the width W_{P2} of the second peak 62, the width W_{P3} of the third peak 63, and the width W_{P4} of the fourth peak 64 may each be a full width at half maximum or a full width at 10% with respect to a local maximum value of the doping concentration (the peak doping concentration) in each peak.

The width W₁₆₂ of the second lattice defect region 162 in the depth direction of the semiconductor substrate 10 may be larger than the width W_{Hp1} of the peak of the hydrogen chemical concentration in the first peak 61, may be larger than the width W_{Hp2} of the peak of the hydrogen chemical concentration in the second peak 62, may be larger than the width W_{Hp3} of the peak of the hydrogen chemical concentration in the third peak 63, or may be larger than the width W_{Hp4} of the peak of the hydrogen chemical concentration in the fourth peak 64. The width W_{Hp1} of the peak of the hydrogen chemical concentration in the first peak 61 may be a full width at half maximum or a full width at 10% with respect to the peak concentration D_{Hp1} of the hydrogen chemical concentration in the first peak 61. The width W_{Hp2} of the peak of the hydrogen chemical concentration in the second peak 62 may be a full width at half maximum or a full width at 10% with respect to the peak concentration D_{Hp2} of the hydrogen chemical concentration in the second peak 62. The width W_{Hp3} of the peak of the hydrogen chemical concentration in the third peak 63 may be a full width at half maximum or a full width at 10% with respect to the peak concentration D_{Hp3} of the hydrogen chemical concentration in the third peak 63. The width W_{Hp4} of the peak of the hydrogen chemical concentration in the fourth peak 64 may be a full width at half maximum or a full width at 10% with respect to the peak concentration D_{Hp4} of the hydrogen chemical concentration in the fourth peak 64.

The width W₁₆₂ of the second lattice defect region 162 in the depth direction of the semiconductor substrate 10 may be 50% or more of the width W_{buf} of the buffer region 20. The width W₁₆₂ of the second lattice defect region 162 in the depth direction may be larger than the sum W_{EX} of the widths of the regions other than the second lattice defect region 162 in the buffer region 20 in the depth direction. By increasing the width W₁₆₂ of the second lattice defect region 162 in the depth direction, trade-offs among the turn-off loss, the inter-collector-emitter saturation voltage, and the leakage current can be improved. By increasing the width W₁₆₂ of the second lattice defect region 162 in the depth direction, the turn-off loss can be made small.

The minimum value D_{2Hp1p2} of the hydrogen chemical concentration in the second lattice defect region 162 may be smaller than the peak concentration D_{P1} of the first peak 61, may be smaller than the peak concentration D_{P2} of the second peak 62, may be smaller than the peak concentration D_{P3} of the third peak 63, may be smaller than the peak concentration D_{P4} of the fourth peak 64, may be smaller than the doping concentration D_{dr} of the drift region 18, or may be smaller than the bulk donor concentration. The minimum value D_{2Hp1p2} of the hydrogen chemical concentration in the second lattice defect region 162 may be smaller than 5×10¹⁴ atoms/cm³, or may be smaller than 1×10¹⁴ atoms/cm³. The minimum value D_{2Hp1p2} of the hydrogen chemical concentration in the second lattice defect region 162 may be larger than 1×10¹² atoms/cm³, or may be larger than 1×10¹³ atoms/cm³. By making the hydrogen chemical concentration in the second lattice defect region 162 small, the lattice defects can be caused to remain widely.

When the depletion layer in the off state crosses the fourth peak 64 toward the back surface 23 side and penetrates into the second lattice defect region 162, the leakage current increases. Thus, the depletion layer may stop inside the fourth peak 64 which is the hydrogen peak. A position at which the integrated concentration reaches the critical integrated concentration may be positioned inside the fourth peak 64. Accordingly, since the depletion layer does not penetrate into the second lattice defect region 162, the leakage current can be prevented from increasing.

FIG. 2G shows a modified example of the doping concentration distribution of the first lattice defect region 161. In addition to that described above, the doping concentration distribution of the first lattice defect region 161 may have a portion in which an absolute value of the gradient of the doping concentration increases from the depth position xₚ₂ at the end portion of the first lattice defect region 161 toward the position x_{rc1} at which the minimum value D_{rc1} is obtained (solid line). The depth position xₚ₂ is positioned in the front surface 21 side relative to a center position x_{center} of the first lattice defect region 161. The depth position x_{rc1} is positioned in the back surface 23 side relative to the center position x_{center} of the first lattice defect region 161. An inclination of a slant portion of a right triangle shown in FIG. 2G indicates a degree of the absolute value of the gradient of the doping concentration. As a length of a vertical line of the right triangle becomes larger, the absolute value of the gradient of the doping concentration becomes larger. The shape of the doping concentration distribution of the first lattice defect region 161 may be an upward convex shape. Regarding the absolute value of the gradient of the doping concentration of the first lattice defect region 161, the absolute value of the gradient of the doping concentration may increase in a region of 50% or more and 100% or less of a width from the depth position xₚ₂ at the end portion of the first lattice defect region 161 to the depth position x_{rc1} of the minimum value.

As indicated by the dashed-dotted line in FIG. 2G, a portion in which the absolute value of the gradient of the doping concentration increases from the position xₚ₁ at the end portion of the first lattice defect region 161 toward the position x_{rc2} at which the minimum value D_{rc1} is obtained may also be provided. The depth position xₚ₁ is positioned in the back surface 23 side relative to the center position x_{center} of the first lattice defect region 161. The depth position x_{rc2} is positioned in the front surface 21 side relative to the center position x_{center} of the first lattice defect region 161. The depth position xₚ₁ is positioned in the back surface 23 side relative to the depth position xₚ₂. The depth position x_{rc1} is positioned in the back surface 23 side relative to the depth position x_{rc2}.

As indicated by the chain double-dashed line in FIG. 2G, a portion in which the absolute value of the gradient of the doping concentration increases from the position xₚ₁ and position xₚ₂ at the end portions of the first lattice defect region 161 toward the position x_{center} at which the minimum value D_{rc1} is obtained may also be provided. The doping concentration distribution of the first lattice defect region 161 may be provided along a distribution obtained by vertically flipping the Gaussian distribution. The doping concentration distribution of the first lattice defect region 161 may be a distribution that is symmetric with respect to the depth position x_{center} in the depth direction.

FIG. 2H shows a modified example of the doping concentration distribution of the first lattice defect region 161. The doping concentration distribution of the first lattice defect region 161 may have a portion in which the absolute value of the gradient of the doping concentration decreases or the absolute value of the gradient is substantially constant from the depth position xₚ₁ at the end portion of the first lattice defect region 161 toward the position x_{rc2} at which the minimum value D_{rc1} is obtained (solid line). The depth position xₚ₁ is positioned in the back surface 23 side relative to the center position x_{center} of the first lattice defect region 161. The depth position x_{rc2} is positioned in the front surface 21 side relative to the center position x_{center} of the first lattice defect region 161. An inclination of a slant portion of a right triangle shown in FIG. 2H indicates a degree of the absolute value of the gradient of the doping concentration. As a length of a vertical line of the right triangle becomes larger, the absolute value of the gradient of the doping concentration becomes larger. The shape of the doping concentration distribution of the first lattice defect region 161 may be a downward convex shape. The absolute value of the gradient of the doping concentration of the first lattice defect region 161 may have a region where the absolute value of the gradient of the doping concentration is substantially constant in a region from the depth position xₚ₁ at the end portion of the first lattice defect region 161 to the depth position x_{rc2} of the minimum value. The absolute value of the gradient being substantially constant may mean that the absolute value of the gradient is within a range of 50% of an average value of the absolute value of the gradient across 30% to 70% of the range between the depth position xₚ₁ and the depth position x_{rc2}.

As indicated by the dashed-dotted line in FIG. 2H, a portion in which the absolute value of the gradient of the doping concentration decreases or the absolute value of the gradient is substantially constant may be provided from the position xₚ₂ at the end portion of the first lattice defect region 161 toward the position x_{rc1} at which the minimum value D_{rc1} is obtained. The depth position xₚ₂ is positioned in the front surface 21 side relative to a center position x_{center} of the first lattice defect region 161. The depth position x_{rc1} is positioned in the back surface 23 side relative to the center position x_{center} of the first lattice defect region 161. The depth position xₚ₁ is positioned in the back surface 23 side relative to the depth position xₚ₂. The depth position x_{rc1} is positioned in the back surface 23 side relative to the depth position x_{rc2}.

As indicated by the dotted line in FIG. 2H, a region where the absolute value of the gradient of the doping concentration increases, a region where it decreases, and a region where the doping concentration is substantially constant may be provided from the position xₚ₁ and the position xₚ₂ at the respective end portions of the first lattice defect region 161 toward the position x_{center} at which the minimum value D_{rc1} is obtained. In other words, the doping concentration distribution of the first lattice defect region 161 may have a downwardly convex shape like a shape of a bowl or a bathtub (dotted line). The doping concentration distribution of the first lattice defect region 161 may be a distribution that is symmetric with respect to the depth position x_{center} in the depth direction. The region where the doping concentration of the first lattice defect region 161 is substantially constant may include the intermediate depth position x_{center} of the first lattice defect region 161 (dotted line). The region where the doping concentration is substantially constant may be a range where the doping concentration includes the minimum value Drc1 and the doping concentration is within ±50% of the minimum value D_{rc1}. The region where the doping concentration is substantially constant may be a depth range that is 30% to 70% of the width between the depth position xₚ₁ and the depth position xₚ₂.

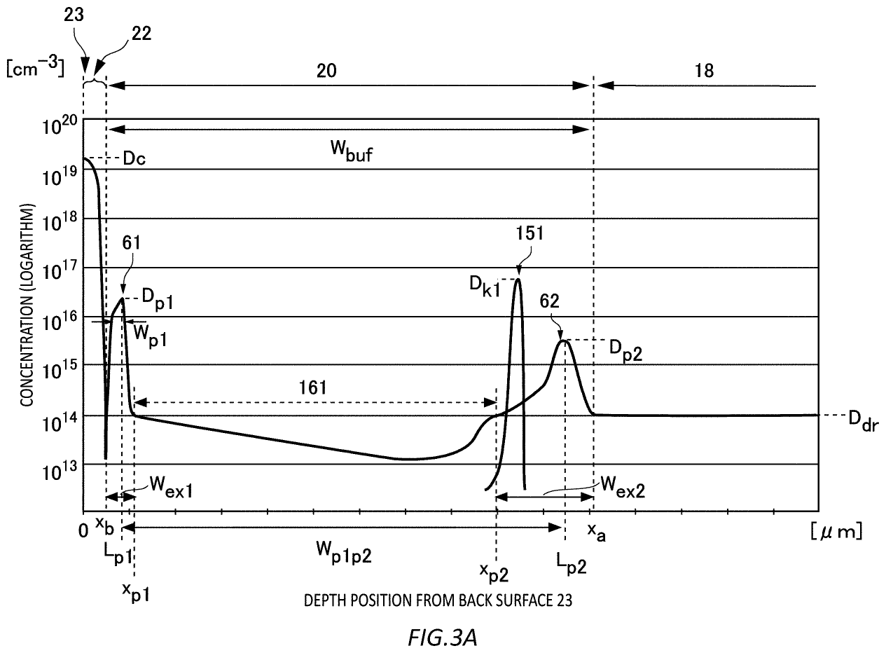

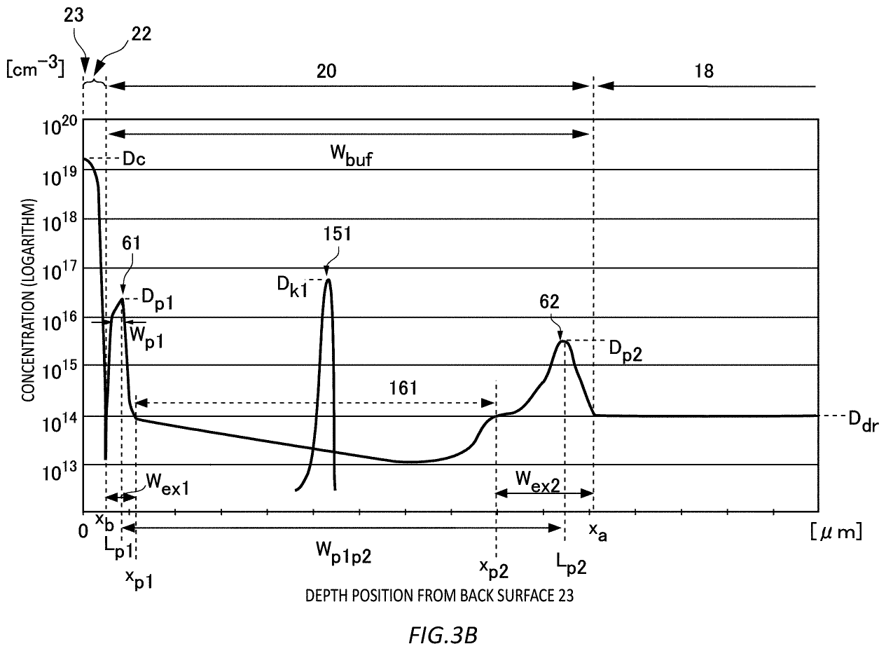

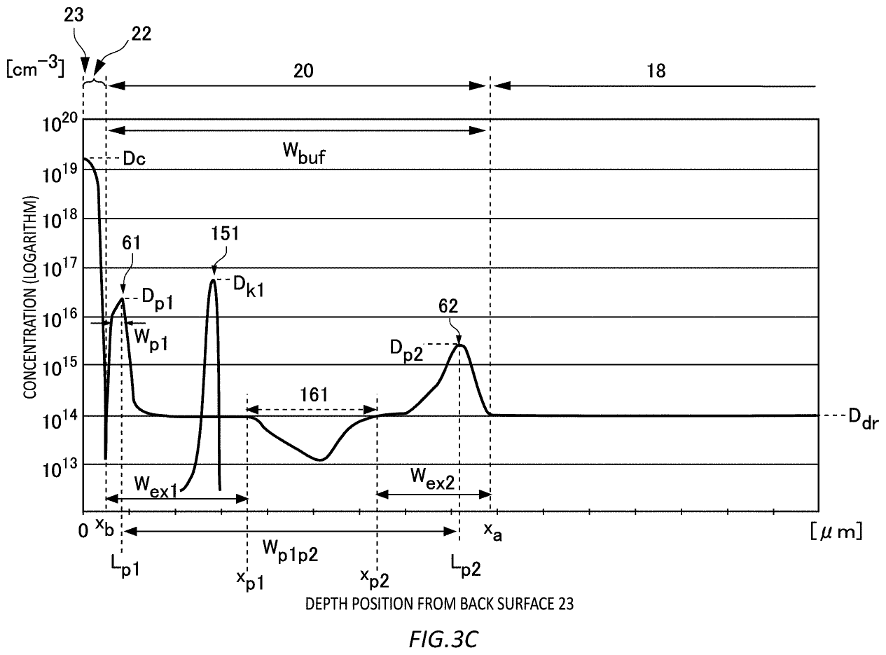

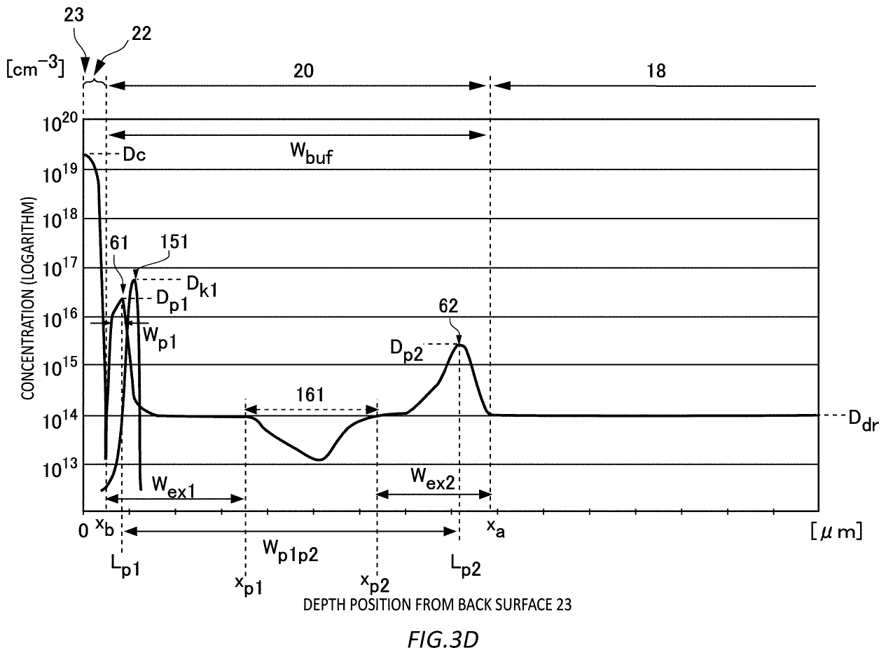

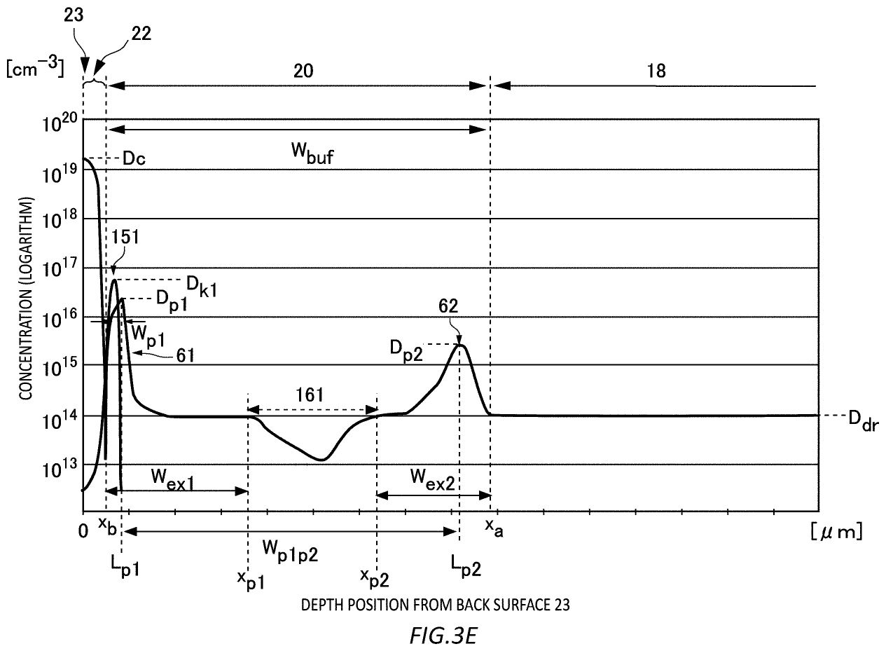

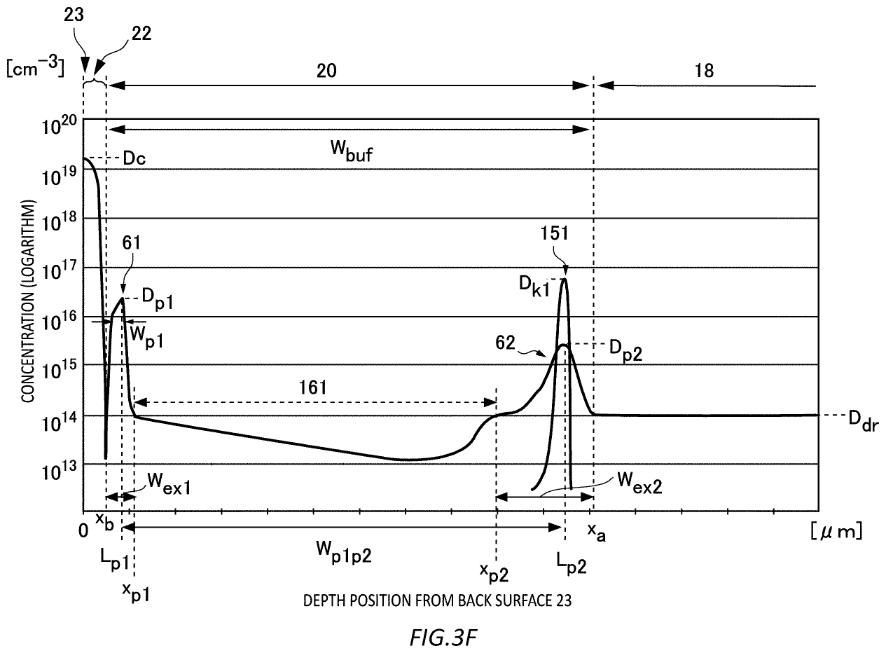

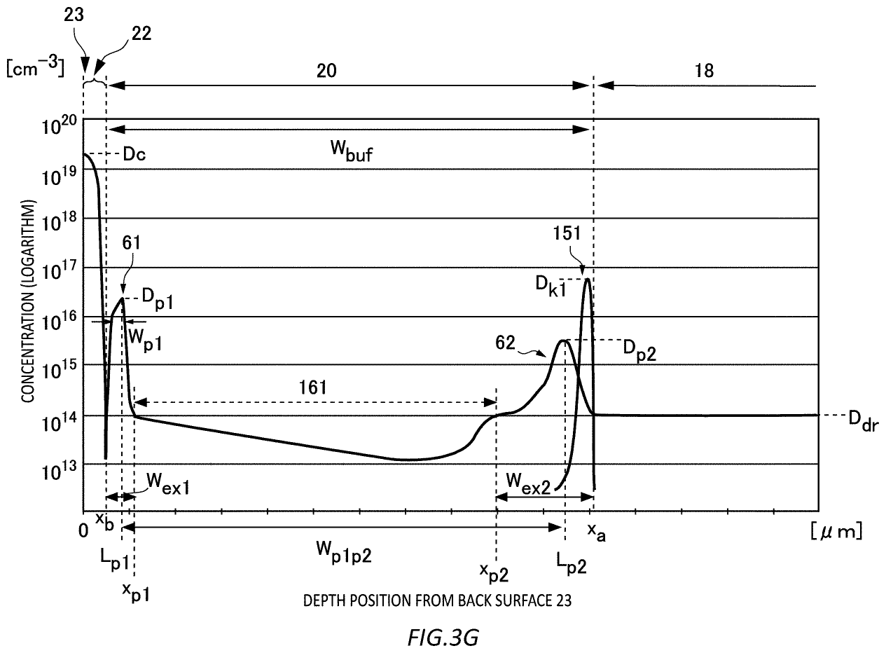

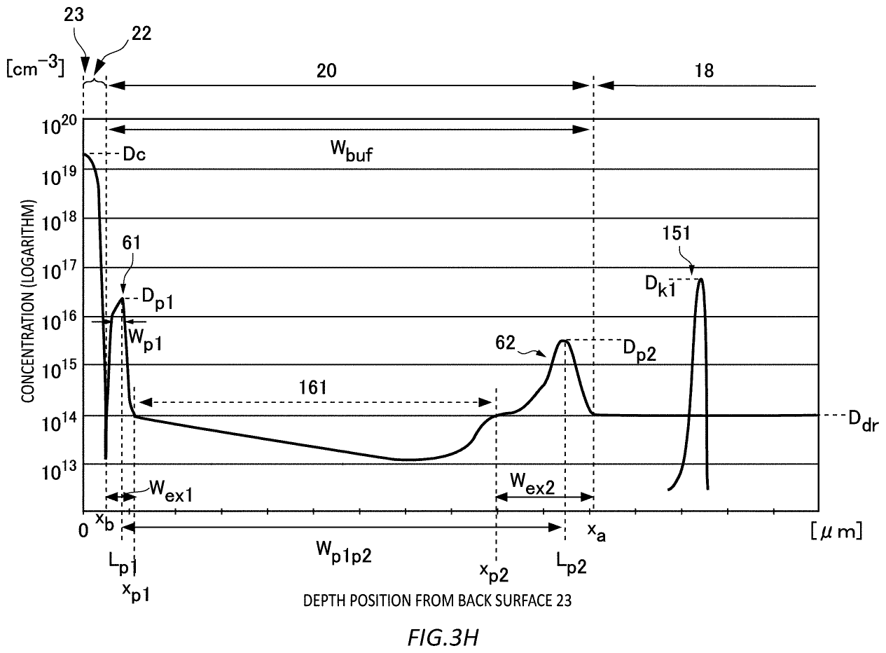

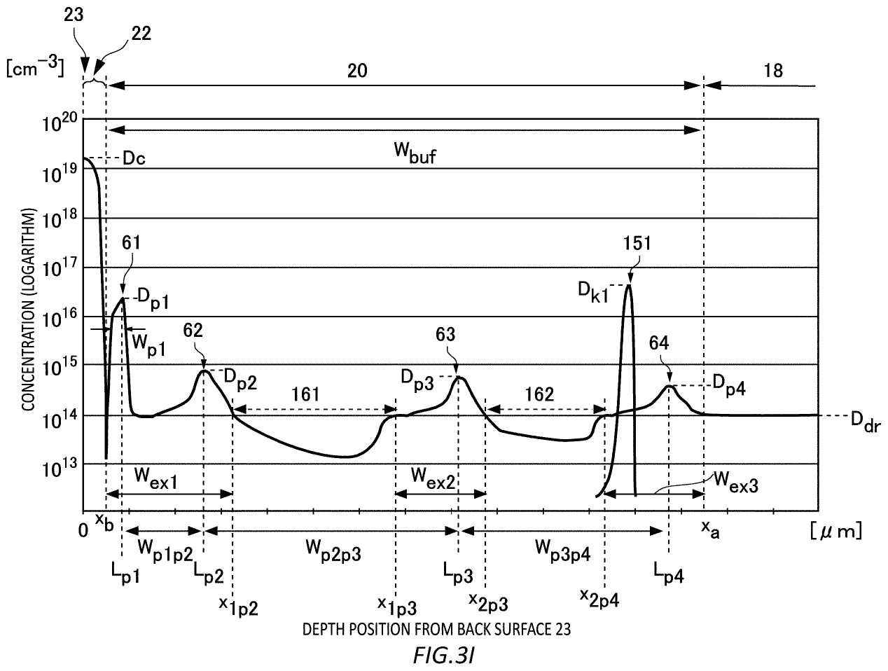

FIG. 3A shows an example of the semiconductor device 100 including a first lifetime control region 151. In the present example, descriptions will be given on a case of providing the first lifetime control region 151 in the example shown in FIG. 2A, but the first lifetime control region 151 may be combined with the semiconductor device 100 disclosed in other examples. The first lifetime control region 151 may be provided at any position of the buffer region 20 in the depth direction of the semiconductor substrate 10. Note that the hydrogen chemical concentration distribution 170 of the hydrogen peak may be omitted in the drawings, but the hydrogen chemical concentration distribution 170 may exist as shown in any of the examples shown in FIGS. 2A to 2F.

A peak position of the first lifetime control region 151 is provided in the front surface 21 side of the semiconductor substrate 10 relative to the first peak 61. Further, the peak position of the first lifetime control region 151 is in the back surface 23 side relative to the hydrogen peak of the buffer region 20 in the depth direction of the semiconductor substrate 10. The peak position of the first lifetime control region 151 of the present example is between the first lattice defect region 161 and the second peak 62 which is the hydrogen peak in the depth direction of the semiconductor substrate 10.

A peak concentration Dₖ₁ is a lifetime killer concentration of the first lifetime control region 151. The lifetime killer concentration may be a concentration at a recombination center. The recombination center may be a complex of vacancies such as a single vacancy and a divacancy, may be an inter-lattice atom (silicon in the present example) of atoms constituting a semiconductor substrate, may be an atom of a noble gas element such as helium, or may be a metal atom of platinum, gold, or the like. The peak concentration Dₖ₁ may be larger than the peak concentration Dₚ₁ of the doping concentration in the first peak 61. The peak concentration Dₖ₁ may be 2 times or more, 5 times or more, or 10 times or more of the peak concentration Dₚ₁. In one example, the peak concentration Dₖ₁ is 1.0 E15 cm⁻³ or more and 1.0 E17 cm⁻³ or less. Note that the peak concentration Dₖ₁ may be smaller than the peak concentration Dc of the doping concentration in the collector region 22.

By forming the peak concentration Dₖ₁ to be larger than the peak concentration Dₚ₁, an effect of hydrogen for forming the buffer region 20 becomes small. That is, while hydrogen for forming the buffer region 20 may terminate the dangling bonds of the lattice defects so as to cause the introduced lattice defects to disappear, by setting the peak concentration Dₖ₁ of the first lifetime control region 151 to be higher than the peak concentration of the buffer region 20, disappearance of the lattice defects can be suppressed. Accordingly, excess carriers in the back surface 23 side during a reverse recovery operation can be sufficiently reduced.

FIG. 3B shows a modified example of the semiconductor device 100 including the first lifetime control region 151. The first lifetime control region 151 of the present example is provided in a region that is the same as the region where the first lattice defect region 161 is formed. The first lifetime control region 151 of the present example is provided at a center of the first lattice defect region 161 in the depth direction of the semiconductor substrate 10, but is not limited thereto. The first lifetime control region 151 may be provided in the back surface 23 side or the front surface 21 side relative to the center of the first lattice defect region 161. Moreover, the first lifetime control region 151 may be provided at a boundary between the first peak 61 and the first lattice defect region 161, or may be provided at a boundary between the first lattice defect region 161 and the second peak 62.

FIG. 3C shows a modified example of the semiconductor device 100 including the first lifetime control region 151. In the present example, descriptions will be given on a case of providing the first lifetime control region 151 in the example shown in FIG. 2B, but the first lifetime control region 151 may be combined with the semiconductor device 100 disclosed in other examples.

The first lifetime control region 151 is provided in the back surface 23 side relative to the first lattice defect region 161 in the depth direction of the semiconductor substrate 10. The first lifetime control region 151 of the present example is provided between the first peak 61 and the first lattice defect region 161. The first lifetime control region 151 may be provided in a region where the doping concentration becomes substantially the same as that of the drift region 18 in the front surface 21 side relative to the first peak 61. Alternatively, a part of the first lifetime control region 151 may be provided in the first lattice defect region 161.

FIG. 3D shows a modified example of the semiconductor device 100 including the first lifetime control region 151. In the present example, the position of the first lifetime control region 151 differs from that of the example shown in FIG. 3C. In the present example, points different from those of the example shown in FIG. 3C will be described in particular. The first lifetime control region 151 of the present example is provided at a tail portion of the first peak 61 between the first peak 61 and the first lattice defect region 161. That is, the peak position of the first lifetime control region 151 is in the front surface 21 side relative to the first peak 61. In this manner, the first lifetime control region 151 may be provided while a part thereof overlaps with the first peak 61.

FIG. 3E shows a modified example of the semiconductor device 100 including the first lifetime control region 151. In the present example, the position of the first lifetime control region 151 differs from that of the examples shown in FIGS. 3C and 3D. In the present example, points different from those of the examples shown in FIGS. 3C and 3D will be described in particular. The first lifetime control region 151 of the present example is provided in the back surface 23 side relative to the first peak 61 in the depth direction of the semiconductor substrate 10. The peak position of the first lifetime control region 151 of the present example is provided between the collector region 22 and the first peak 61.

FIG. 3F shows a modified example of the semiconductor device 100 including the first lifetime control region 151. In the present example, the position of the first lifetime control region 151 differs from that of the examples shown in FIGS. 3A and 3B. In the present example, points different from those of the examples shown in FIGS. 3A and 3B will be described in particular. The first lifetime control region 151 of the present example has a peak of the doping concentration at the same position as the depth position Lₚ₂ of the second peak 62 in the depth direction of the semiconductor substrate 10. Note that when the buffer region 20 has a plurality of hydrogen peaks such as the third peak 63 or the fourth peak 64, the first lifetime control region 151 may be provided at the same position as the depth position of any of the hydrogen peaks.

FIG. 3G shows a modified example of the semiconductor device 100 including the first lifetime control region 151. In the present example, the position of the first lifetime control region 151 differs from that of the examples shown in FIGS. 3A, 3B, and 3F. In the present example, points different from those of the examples shown in FIGS. 3A, 3B, and 3F will be described in particular.

The peak position of the first lifetime control region 151 of the present example is between the hydrogen peak of the buffer region 20 and the drift region 18 in the depth direction of the semiconductor substrate 10. That is, the peak position of the first lifetime control region 151 of the present example is provided in the front surface 21 side relative to the second peak 62 in the depth direction of the semiconductor substrate 10. Moreover, the peak position of the first lifetime control region 151 is provided in the back surface 23 side relative to the drift region 18.

Herein, since the peak position of the first lifetime control region 151 is provided close to the second peak 62 even when it is provided in the front surface 21 side relative to the second peak 62, the dangling bonds of the lattice defects in the first lifetime control region 151 are terminated by hydrogen, and thus a rise in leakage current can be suppressed. Close to the second peak 62 means that the peak position of the first lifetime control region 151 is provided between the second peak 62 and the drift region 18, for example. That is, the peak position of the first lifetime control region 151 may be provided on an inner side of a tail in the front surface 21 side of the second peak 62.

FIG. 3H shows a modified example of the semiconductor device 100 including the first lifetime control region 151. The peak position of the first lifetime control region 151 of the present example is provided in the drift region 18 while being set apart from the hydrogen peak of the buffer region 20 in the depth direction of the semiconductor substrate 10. Even when the peak position of the first lifetime control region 151 is provided in the front surface 21 side apart from the second peak 62, since lifetime control is also performed by the first lattice defect region 161, the first lifetime control region 151 can be formed by low-dose helium ion implantation instead of high-dose ion implantation, and thus the rise in leakage current can be suppressed.

FIG. 3I shows a modified example of the semiconductor device 100 including the first lifetime control region 151. In the present example, descriptions will be given on a case of providing the first lifetime control region 151 in the example shown in FIG. 2F, but the first lifetime control region 151 may be combined with the semiconductor device 100 disclosed in other examples.

The first lifetime control region 151 is provided between the second lattice defect region 162 and the fourth peak 64. In this case, as will be described later, the fourth peak 64 may function as a field stop layer which prevents the depletion layer expanding from the lower surface side of the base region 14 from reaching the collector region 22 of the second conductivity type.

Alternatively, the first lifetime control region 151 may be provided between the first lattice defect region 161 and the third peak 63. In this case, the third peak 63 and the fourth peak 64 may function as a field stop layer which prevents the depletion layer expanding from the lower surface side of the base region 14 from reaching the collector region 22 of the second conductivity type.

Note that the arrangement methods of the first lifetime control region 151 disclosed in FIGS. 3A to 31 may also be used in combination with the plurality of peaks of the buffer region 20 shown in FIGS. 2A to 2F as appropriate. By changing the positions of the first lifetime control region 151 and the first lattice defect region 161 as appropriate, switching characteristics can be improved while suppressing an increase in leakage current.

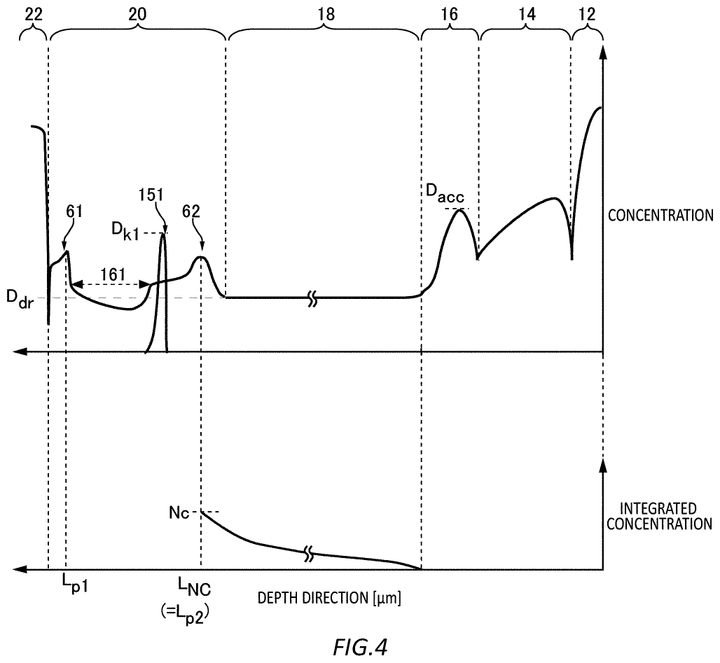

FIG. 4 shows an example of the doping concentration distribution in the semiconductor substrate 10. The present figure also shows the doping concentration distribution of the first lifetime control region 151. In addition, the present figure also shows an integrated concentration from an upper end of the drift region 18.

In the present specification, a value obtained by integrating the doping concentration from the lower surface side of the base region 14 to a particular position of the semiconductor substrate 10 along the depth direction of the semiconductor substrate 10 is referred to as the integrated concentration. In addition, in the present specification, in a case where a forward bias is applied between the collector electrode 24 and the emitter electrode 52 and a maximum value of an electric field intensity has reached a critical electric field intensity to thus cause an avalanche breakdown, and in a case where the semiconductor substrate 10 is depleted from the lower surface of the base region 14 to a particular position thereof in the depth direction, it is expressed that the integrated concentration reaches the critical integrated concentration Nc. Note that in the semiconductor device 100, a forward bias being applied between the collector electrode 24 and the emitter electrode 52 means that a potential of the collector electrode 24 is higher than a potential of the emitter electrode 52 in a state where the gate is off. When an avalanche breakdown occurs in the semiconductor device 100, an avalanche current flows between the collector electrode 24 and the emitter electrode 52, and an increase of a voltage V_{CE} between the collector electrode 24 and the emitter electrode 52 stops. In this case, the depletion layer does not expand in the back surface side relative to a position L_{Nc} at which the integrated concentration reaches the critical integrated concentration Nc.

In the present example, the integrated concentration obtained by integrating the doping concentration in a direction from the upper end of the drift region 18 to the hydrogen peak included in the buffer region 20 in the depth direction of the semiconductor substrate 10 is equal to or larger than the critical integrated concentration Nc. More specifically, the first lattice defect region 161 may be provided in the back surface 23 side relative to the second peak 62, and the integrated concentration from the upper end of the drift region 18 to the second peak 62 in the depth direction of the semiconductor substrate 10 may be equal to or larger than the critical integrated concentration Nc. The position L_{Nc} at which the critical integrated concentration Nc is reached may be identical to the depth position Lₚ₂ of the second peak 62. Accordingly, since the depletion layer expanding from the lower surface side of the base region 14 is stopped by the second peak 62, the peak of the first lattice defect region 161 can be arranged in a non-depleted region. Thus, an increase in leakage current due to the formation of the first lattice defect region 161 can also be suppressed. By a similar reason, the first lifetime control region 151 may be provided in the back surface 23 side relative to the second peak 62.

The position L_{Nc} at which the critical integrated concentration Nc is reached and the peak position of the buffer region 20 (the depth position Lₚ₂ of the second peak 62 in the present example) may not be identical. The position L_{Nc} at which the critical integrated concentration Nc is reached may be positioned in the front surface 21 side relative to the depth position Lₚ₂ of the second peak 62. That is, any of the hydrogen peaks included in the buffer region 20 only needs to be capable of stopping the depletion layer before the depletion layer reaches the first lattice defect region 161. The position L_{Nc} at which the critical integrated concentration Nc is reached may be the depth position Lₚ₃ of the third peak 63 or the depth position Lₚ₄ of the fourth peak 64.

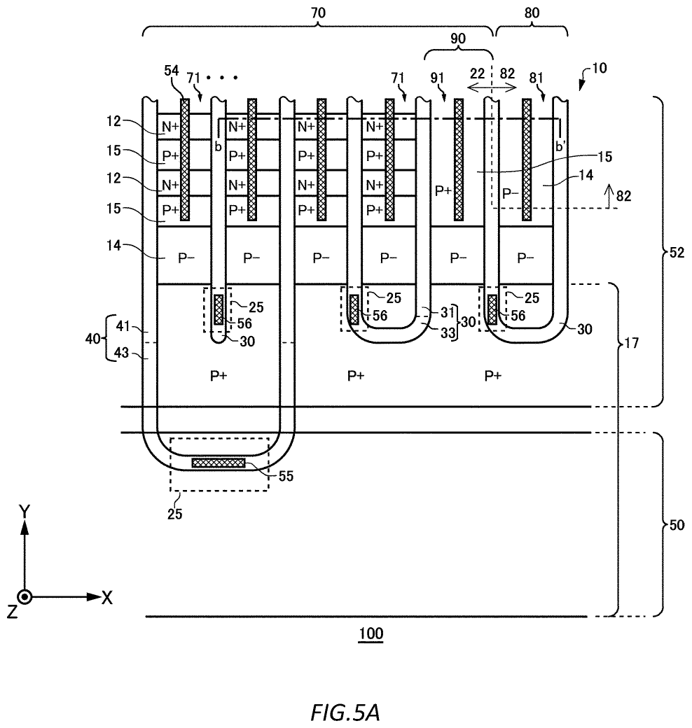

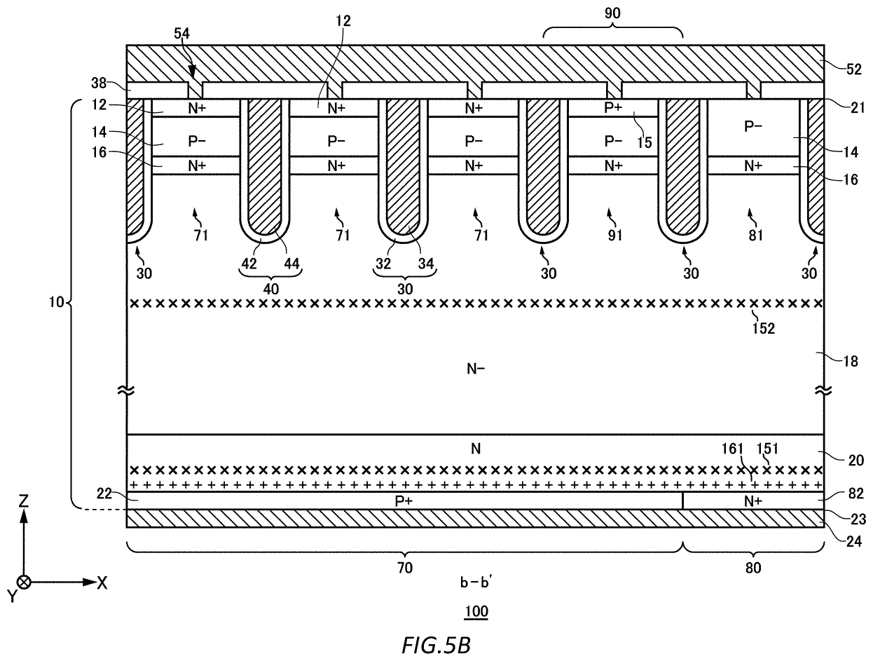

FIG. 5A shows a top view of a modified example of the semiconductor device 100. The semiconductor device 100 of the present example includes the transistor portion 70 and the diode portion 80. For example, the semiconductor device 100 is a reverse conducting IGBT (RC-IGBT: Reverse Conducting IGBT). The transistor portion 70 of the present example includes a boundary portion 90 that is positioned at a boundary between the transistor portion 70 and the diode portion 80.

The diode portion 80 is a region obtained by projecting the cathode region 82 provided in the back surface 23 side of the semiconductor substrate 10 onto the upper surface of the semiconductor substrate 10. The cathode region 82 is of the first conductivity type. The cathode region 82 of the present example is of an N+ type, as an example. The diode portion 80 includes diodes such as free wheel diodes (FWD: Free Wheel Diode) provided while being adjacent to the transistor portion 70 on the upper surface of the semiconductor substrate 10.

The boundary portion 90 is a region which is provided in the transistor portion 70 and is in direct contact with the diode portion 80. The boundary portion 90 includes the contact region 15. The boundary portion 90 of the present example does not include the emitter region 12. In one example, the trench portions in the boundary portion 90 are the dummy trench portions 30. The boundary portion 90 of the present example is arranged such that both ends thereof in the X axis direction become the dummy trench portions 30.

The contact hole 54 is provided above the base region 14 in the diode portion 80. The contact hole 54 is provided above the contact region 15 in the boundary portion 90. No contact hole 54 is provided above the well regions 17 provided at both ends in the Y axis direction.

A mesa portion 91 is provided between the plurality of trench portions in the boundary portion 90. The mesa portion 91 includes the contact region 15 at the front surface 21 of the semiconductor substrate 10. The mesa portion 91 of the present example includes the base region 14 and the well region 17 on a negative side of the Y axis direction.

The mesa portion 81 is provided in a region interposed between the dummy trench portions 30 adjacent to each other in the diode portion 80. The mesa portion 81 includes the contact region 15 at the front surface 21 of the semiconductor substrate 10. The mesa portion 81 of the present example includes the base region 14 and the well region 17 on the negative side of the Y axis direction.

The emitter region 12 is provided in the mesa portion 71, but does not need to be provided in the mesa portion 81 and the mesa portion 91. The contact region 15 is provided in the mesa portion 71 and the mesa portion 91, but does not need to be provided in the mesa portion 81.

FIG. 5B shows a cross section b-b′ of the modified example of the semiconductor device 100. The semiconductor device 100 of the present example includes the first lifetime control region 151 and the second lifetime control region 152. The buffer region 20 may have the configuration of any of the examples. That is, the number and positions of the peaks included in the buffer region 20 are not limited in particular.

The contact region 15 is provided above the base region 14 in the mesa portion 91. The contact region 15 is provided in contact with the dummy trench portions 30 in the mesa portion 91. In another cross section, the contact region 15 may be provided at the front surface 21 in the mesa portion 71.

The accumulation region 16 is provided in the transistor portion 70 and the diode portion 80. The accumulation region 16 of the present example is provided on entire surfaces of the transistor portion 70 and the diode portion 80. It is to be noted that the accumulation region 16 does not need to be provided in the diode portion 80.

The cathode region 82 is provided below the buffer region 20 in the diode portion 80. A boundary between the collector region 22 and the cathode region 82 is a boundary between the transistor portion 70 and the diode portion 80. That is, the collector region 22 is provided below the boundary portion 90 of the present example.

The first lattice defect region 161 is provided in both the transistor portion 70 and the diode portion 80. Accordingly, in the semiconductor device 100 of the present example, a recovery speed in the diode portion 80 can be raised, and a switching loss can be further improved. The position of the first lattice defect region 161 in the depth direction may be the position according to any of the examples.

The first lifetime control region 151 is provided in both of the transistor portion 70 and the diode portion 80. Accordingly, in the semiconductor device 100 of the present example, a recovery speed in the diode portion 80 can be raised, and a switching loss can be further improved. The first lifetime control region 151 may be formed at the position according to any of the examples.

The second lifetime control region 152 is a region where a lifetime killer is intentionally formed by implanting an impurity into the semiconductor substrate 10, or the like. The second lifetime control region 152 is provided in the front surface 21 side relative to a center of the semiconductor substrate 10 in the depth direction of the semiconductor substrate 10. The second lifetime control region 152 of the present example is provided in the drift region 18. The second lifetime control region 152 may be provided in the diode portion 80. Alternatively, the second lifetime control region 152 may be provided in both of the transistor portion 70 and the diode portion 80. The second lifetime control region 152 of the present example is provided in both of the transistor portion 70 and the diode portion 80. The second lifetime control region 152 may be formed by implanting an impurity from the front surface 21 side, or may be formed by implanting an impurity from the back surface 23 side. The second lifetime control region 152 may be provided in the diode portion 80 and the boundary portion 90 and not be provided in a part of the transistor portion 70.

The second lifetime control region 152 may be formed by any method. Elements, dose amounts, and the like for forming the first lifetime control region 151 and the second lifetime control region 152 may be the same or may be different. The second lifetime control region 152 may be formed by ion implantation of hydrogen, helium, or the like, or by electron beam irradiation.

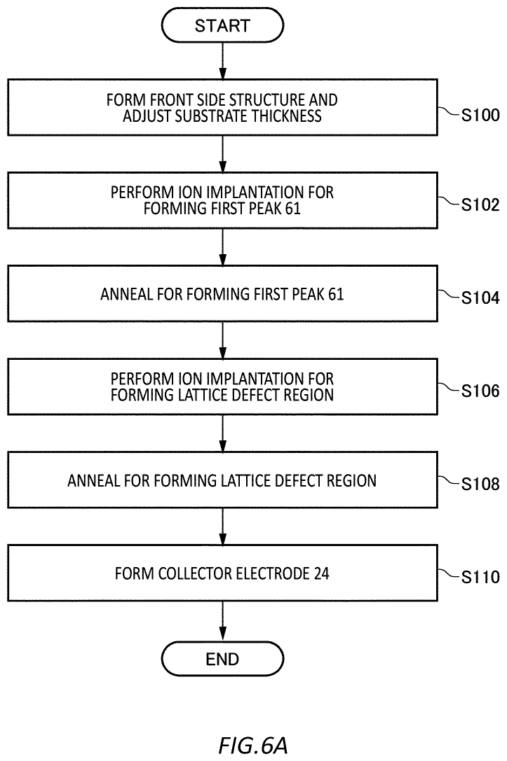

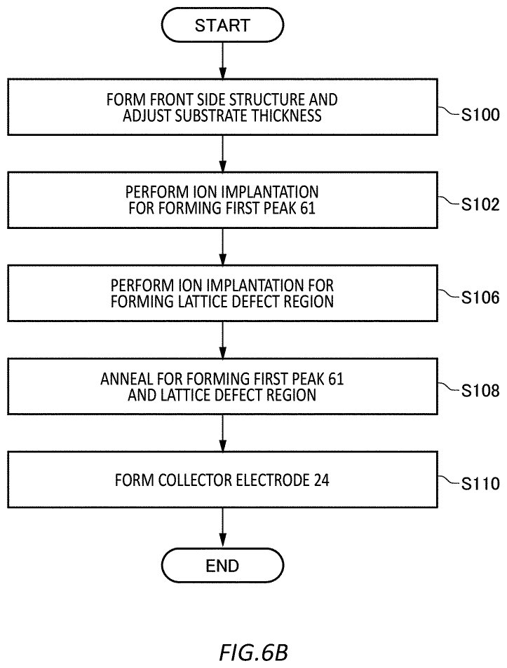

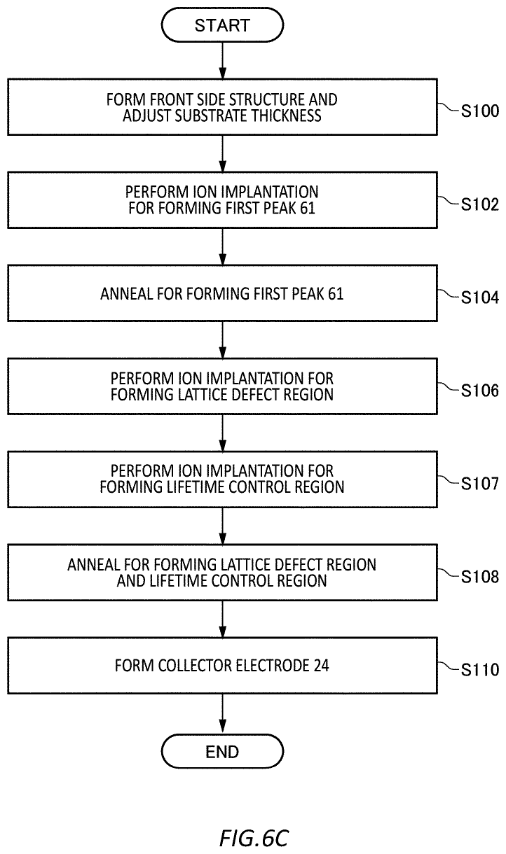

FIG. 6A is a flowchart showing an example of a manufacturing process of the semiconductor device 100. In Step S100, a front surface side structure of the semiconductor device 100 is formed. Further, in Step S100, after forming the front surface side structure, the back surface 23 side of the semiconductor substrate 10 is grinded so as to adjust the thickness of the semiconductor substrate 10 according to a required breakdown voltage.

In Step S102, ion implantation is performed from the back surface 23 side of the semiconductor substrate 10 for forming the first peak 61. The first peak 61 may be formed by phosphorus ion implantation, may be formed by hydrogen ion implantation, or may be formed by other methods.

For example, when phosphorus is used for the first peak 61, a dose amount of the dopant of the first peak 61 may be 1.0 E12 cm⁻² or more, or may be 2.0 E12 cm⁻² or more. The dose amount of the dopant of the first peak 61 may be 1.0 E13 cm⁻² or less, or may be 5.0 E12 cm⁻² or less. The dose amount of the dopant of the first peak 61 in the present example is 3.0 E12 cm⁻² Acceleration energy of the dopant of the first peak 61 may be 500 keV or more, or may be 700 keV or more. The acceleration energy of the dopant of the first peak 61 may be 4,000 keV or less, or may be 3,000 keV or less. The acceleration energy of the dopant of the first peak 61 in the present example is 2,000 keV.

In Step S104, the semiconductor substrate 10 is annealed for forming the first peak 61. That is, in the present example, the semiconductor substrate 10 is annealed after the ion implantation of the first peak 61 and before the ion implantation of the lattice defect region. For example, in Step S104, the back surface 23 of the semiconductor substrate 10 is heated by laser annealing. Alternatively, in Step S104, the semiconductor substrate 10 may be heated by an annealing furnace in a nitrogen atmosphere or the like. An annealing temperature in the annealing furnace may be 350 degrees or more and 420 degrees or less. An annealing time may be 10 minutes or more and 20 hours or less.

In Step S106, ion implantation is performed from the back surface 23 side of the semiconductor substrate 10 for forming the lattice defect region. In the present example, hydrogen ion implantation is performed for forming the first lattice defect region 161 after the annealing for forming the first peak 61. The first lattice defect region 161 is formed by hydrogen ion implantation in the front surface 21 side relative to the first peak 61 in the depth direction of the semiconductor substrate 10. When forming a plurality of hydrogen peaks in the buffer region 20, hydrogen ions may be implanted a plurality of times while differentiating the acceleration energy.

The first lattice defect region 161 may be formed by the ion implantation for forming any of the hydrogen peaks of the buffer region 20. That is, the first lattice defect region 161 may be formed by the ion implantation for forming the second peak 62, may be formed by the ion implantation for forming the third peak 63, or may be formed by the ion implantation for forming the fourth peak 64.

As an example, the dose amount of the hydrogen ions corresponding to the second peak 62 is 7.0×10¹²/cm², and the acceleration energy is 1,100 keV. The dose amount of the hydrogen ions corresponding to the third peak 63 is 1.0×10¹³/cm², and the acceleration energy is 800 keV. The dose amount of the hydrogen ions corresponding to the fourth peak 64 is 3.0×10¹⁴/cm², and the acceleration energy is 300 keV.

In Step S108, the semiconductor substrate 10 is annealed for forming the lattice defect region. The semiconductor substrate 10 may be heated by the annealing furnace in a hydrogen or nitrogen atmosphere or the like. In one example, the annealing for forming the first lattice defect region 161 is executed at a temperature lower than that of the annealing for forming the first peak 61. In addition, the annealing for forming the first lattice defect region 161 may be executed in a shorter time than in the annealing for forming the first peak 61. For example, the annealing temperature for forming the first lattice defect region 161 may be 350 degrees or more and 380 degrees or less. The annealing time may be 10 minutes or more and 3 hours or less.

In Step S110, the collector electrode 24 is formed. The collector electrode 24 may be formed on the entire surface of the back surface 23. For example, the collector electrode 24 is formed by a sputtering method. The collector electrode 24 may be a laminated electrode in which an aluminum layer, a titanium layer, a nickel layer, and the like are laminated. The semiconductor device 100 can be manufactured by the processes as described above.

Note that Step S102 and Step S104 may be replaced with Step S106 and Step S108. That is, Step S100, Step S106, Step S108, Step S102, Step S104, and Step S110 may be executed in the stated order.

FIG. 6B is a flowchart showing a modified example of the manufacturing process of the semiconductor device 100. In the present example, points different from those of the example shown in FIG. 6A will be described in particular. The semiconductor device 100 of the present example differs from that of FIG. 6A in that annealing of the first peak 61 and that of the lattice defect region are executed simultaneously.

In Step S102, hydrogen ion implantation may be performed for forming the first peak 61. By performing the hydrogen ion implantation for the first peak 61, it becomes easy to share with the annealing for forming the lattice defect region. In the present example, the annealing process only for the first peak 61 in Step S104 shown in FIG. 6A is omitted. A hydrogen ion implantation condition for forming the lattice defect region in Step S106 may be the same as the implantation condition in Step S106 shown in FIG. 6A.

In Step S108, annealing for forming the first peak 61 and that for forming the lattice defect region are executed simultaneously after the ion implantation for forming the lattice defect region. In the present example, the annealing process is shared between the first peak 61 and the first lattice defect region 161. When the semiconductor device 100 includes the second lattice defect region 162, the annealing process may be shared among the first peak 61, the first lattice defect region 161, and the second lattice defect region 162. Accordingly, the annealing process for forming the buffer region 20 can be simplified.

FIG. 6C is a flowchart showing a modified example of the manufacturing process of the semiconductor device 100. In the present example, points different from those of the example shown in FIG. 6A will be described in particular. The present example differs from the example shown in FIG. 6A in the point of further forming the lifetime control region.

In Step S107, ion implantation for forming the lifetime control region is executed. For example, helium ion implantation is performed for forming the first lifetime control region 151. An impurity dose amount for forming the first lifetime control region 151 may be 0.5 E10 cm⁻² or more and 1.0 E13 cm⁻² or less, or may be 5.0 E10 cm⁻² or more and 5.0 E11 cm⁻² or less. The acceleration energy for forming the first lifetime control region 151 may be 50 keV or more and 2,000 keV or less. While the ion implantation of the lifetime control region is executed after executing the ion implantation of the lattice defect region in Step S106 in the present example, the ion implantation of the lattice defect region may alternatively be executed after executing the ion implantation of the lifetime control region.

In Step S108, the semiconductor substrate 10 is annealed for forming the lattice defect region and the lifetime control region. Since the annealing process is shared between the lattice defect region and the lifetime control region in this manner, the annealing process for forming the buffer region 20 can be simplified. For example, in Step S108, the semiconductor substrate 10 is heated by the annealing furnace in a nitrogen atmosphere or the like.

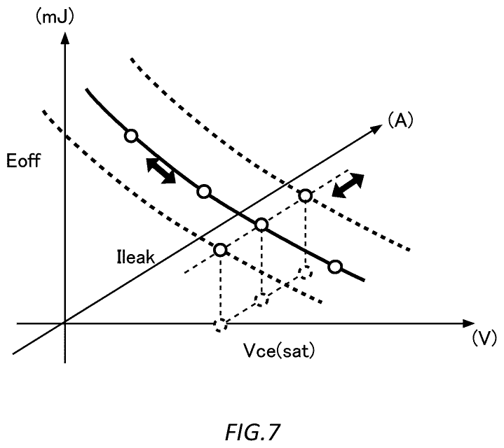

FIG. 7 is a diagram for describing electrical characteristics of the semiconductor device 100. The present figure shows three axes respectively representing a turn-off loss Eoff (mJ), an inter-collector-emitter saturation voltage Vce (sat), and a leakage current lleak (A). Since the semiconductor device 100 of the present example has the hydrogen peak for stopping the depletion layer expanding from the lower surface side of the base region 14 and has the lattice defect region in the back surface 23 side relative to the hydrogen peak, the electrical characteristics of the semiconductor device 100 can be improved.

For example, by adjusting the position of the first lifetime control region 151 or the first lattice defect region 161, or the like, the trade-off between the turn-off loss Eoff and the inter-collector-emitter saturation voltage Vce can be improved. By using the first lifetime control region 151 and the first lattice defect region 161 in combination, it becomes easier to reduce the leakage current at any position of the turn-off loss Eoff and the inter-collector-emitter saturation voltage Vce than in the case of using the first lattice defect region 161 alone.

Moreover, since the semiconductor device 100 has the hydrogen peak for stopping the depletion layer in the front surface 21 side relative to the first lattice defect region 161, an increase in leakage current Ileak can be suppressed. In other words, even when a defect density in the buffer region 20 is raised, a connection between the depletion layer and the first lattice defect region 161 can be avoided, so an increase in leakage current Ileak can be suppressed while improving the trade-off between the turn-off loss Eoff and the inter-collector-emitter saturation voltage Vce. That is, the trade-offs among the three axes of the saturation voltage Vce axis, the turn-off loss Eoff axis, and the leakage current Ileak axis can be improved simultaneously. By adjusting the structure of the buffer region 20 according to desired electrical characteristics in the semiconductor device 100 in this manner, the trade-offs among the turn-off loss Eoff, the inter-collector-emitter saturation voltage Vce, and the leakage current Ileak can be improved.

While the embodiment of the present invention has been described, the technical scope of the invention is not limited to the above-described embodiment. It is apparent to persons skilled in the art that various alterations and improvements can be added to the above described embodiments. It is also apparent from the description of the claims that embodiments added with such alterations or improvements can be included in the technical scope of the present invention.

The operations, procedures, steps, and stages of each process performed by a device, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### EXPLANATION OF REFERENCES

10: semiconductor substrate; 12: emitter region; 14: base region; 15: contact region; 16: accumulation region; 17: well region; 18: drift region; 20: buffer region; 21: front surface; 22: collector region; 23: back surface; 24: collector electrode; 25: connection portion; 30: dummy trench portion; 31: extending portion; 32: dummy dielectric film; 33: connecting portion; 34: dummy conductive portion; 38: interlayer dielectric film; 40: gate trench portion; 41: extending portion; 42: gate dielectric film; 43: connecting portion; 44: gate conductive portion; 50: gate metal layer; 52: emitter electrode; 54: contact hole; 55: contact hole; 56: contact hole; 61: first peak; 62: second peak; 63: third peak; 64: fourth peak; 70: transistor portion; 71: mesa portion; 80: diode portion; 81: mesa portion; 82: cathode region; 90: boundary portion; 91: mesa portion; 100: semiconductor device; 151: first lifetime control region; 152: second lifetime control region; 161: first lattice defect region; 162: second lattice defect region; 170: hydrogen chemical concentration distribution; 171: hydrogen chemical concentration peak; 172: hydrogen chemical concentration peak; 173: hydrogen chemical concentration peak; 174: hydrogen chemical concentration peak.

What is claimed is:

1. A semiconductor device comprising:
a drift region of a first conductivity type which is provided in a semiconductor substrate;
a buffer region of the first conductivity type which is provided in a back surface side of the semiconductor substrate relative to the drift region and has a first peak of a doping concentration; and
a first lattice defect region which is provided in a front surface side of the semiconductor substrate relative to the first peak in a depth direction of the semiconductor substrate and has a recombination center, wherein
the buffer region has a hydrogen peak which is provided in the front surface side of the semiconductor substrate relative to the first lattice defect region and corresponds to a hydrogen chemical concentration peak of a hydrogen chemical concentration distribution,
an integrated concentration obtained by integrating the doping concentration in a direction from an upper end of the drift region to the hydrogen peak in the depth direction of the semiconductor substrate is equal to or larger than a critical integrated concentration, and
an integrated concentration obtained by integrating the doping concentration in a direction from the upper end of the drift region to an upper end of the first lattice defect region in the depth direction of the semiconductor substrate is equal to or larger than the critical integrated concentration.

2. The semiconductor device according to claim 1, wherein
the first peak is a peak closest to the back surface of the semiconductor substrate out of a plurality of peaks included in the buffer region.

3. The semiconductor device according to claim 1, wherein
the hydrogen peak includes a second peak second closest to the back surface of the semiconductor substrate after the first peak out of a plurality of peaks included in the buffer region.

4. The semiconductor device according to claim 3, wherein
the first lattice defect region is provided between the first peak and the second peak in the depth direction of the semiconductor substrate.

5. The semiconductor device according to claim 3, wherein
a recombination center density in the back surface side of the semiconductor substrate relative to the hydrogen peak is higher than a recombination center density in the drift region in a side adjacent to the hydrogen peak.

6. The semiconductor device according to claim 3, wherein
an interval between the first peak and the second peak is 5.0 μm or more in the depth direction of the semiconductor substrate, and is half or less of a thickness of the semiconductor substrate in the depth direction.

7. The semiconductor device according to claim 1, wherein
a width of the first lattice defect region in the depth direction of the semiconductor substrate is 25% or more of an interval between the first peak and the hydrogen peak.

8. The semiconductor device according to claim 1, wherein
a width of the first lattice defect region in the depth direction of the semiconductor substrate is larger than a width of the first peak in the depth direction of the semiconductor substrate.

9. The semiconductor device according to claim 1, wherein
a width of the first lattice defect region in the depth direction of the semiconductor substrate is larger than a width of the hydrogen peak in the depth direction of the semiconductor substrate.

10. The semiconductor device according to claim 1, wherein
a width of the first lattice defect region in the depth direction of the semiconductor substrate is larger than a sum of widths of regions other than the first lattice defect region in the buffer region.

11. The semiconductor device according to claim 1, wherein
a minimum value of the hydrogen chemical concentration distribution in the first lattice defect region is smaller than a peak concentration of the doping concentration in the first peak.

12. The semiconductor device according to claim 1, wherein
a distance between an intermediate depth position of the first lattice defect region and an end of the first lattice defect region in the back surface side is larger than a distance between the intermediate depth position of the first lattice defect region and an end of the first lattice defect region in the front surface side.

13. The semiconductor device according to claim 1, wherein
the buffer region has the first peak and a plurality of hydrogen peaks formed by hydrogen ion implantation.

14. The semiconductor device according to claim 13, wherein
the first lattice defect region is provided between the plurality of hydrogen peaks in the depth direction of the semiconductor substrate.

15. The semiconductor device according to claim 13, comprising:
a second lattice defect region provided between the plurality of hydrogen peaks in the front surface side of the semiconductor substrate relative to the first lattice defect region in the depth direction of the semiconductor substrate.

16. The semiconductor device according to claim 1, wherein
a doping concentration of the hydrogen peak is 1.0 E14 cm⁻³ or more and 1.0 E16 cm⁻³ or less.

17. The semiconductor device according to claim 1, comprising:
a first lifetime control region provided in the front surface side of the semiconductor substrate relative to the first peak in the depth direction of the semiconductor substrate.

18. The semiconductor device according to claim 17, wherein
the first lifetime control region contains helium.

19. The semiconductor device according to claim 17, wherein
a peak position of the first lifetime control region is in the back surface side of the semiconductor substrate relative to the hydrogen peak in the depth direction of the semiconductor substrate.

20. The semiconductor device according to claim 17, wherein
a peak position of the first lifetime control region is between the first lattice defect region and the hydrogen peak in the depth direction of the semiconductor substrate.

21. The semiconductor device according to claim 17, wherein
a peak position of the first lifetime control region is provided in the back surface side of the semiconductor substrate relative to the first lattice defect region in the depth direction of the semiconductor substrate.

22. The semiconductor device according to claim 17, wherein
a peak position of the first lifetime control region is between the hydrogen peak and the drift region in the depth direction of the semiconductor substrate.

23. The semiconductor device according to claim 1, wherein
a dopant of the first peak is phosphorus.

24. The semiconductor device according to claim 1, wherein
a dopant of the first peak is hydrogen.

25. The semiconductor device according to claim 1, wherein
a doping concentration of the first lattice defect region is lower than or equal to a doping concentration of the drift region.

26. The semiconductor device according to claim 1, wherein
a doping concentration of the first lattice defect region is lower than or equal to a bulk donor concentration.

27. A manufacturing method of a semiconductor device comprising:
forming a drift region of a first conductivity type in a semiconductor substrate;
forming, in a back surface side of the semiconductor substrate relative to the drift region, a buffer region of the first conductivity type which has a first peak of a doping concentration; and
forming, in a front surface side of the semiconductor substrate relative to the first peak in a depth direction of the semiconductor substrate, a first lattice defect region formed by hydrogen ion implantation, wherein
the forming of the buffer region includes forming a hydrogen peak that is provided in the front surface side of the semiconductor substrate relative to the first lattice defect region and is formed by hydrogen ion implantation,
an integrated concentration obtained by integrating the doping concentration in a direction from an upper end of the drift region to the hydrogen peak in the depth direction of the semiconductor substrate is equal to or larger than a critical integrated concentration, and
an integrated concentration obtained by integrating the doping concentration in a direction from the upper end of the drift region to an upper end of the first lattice defect region in the depth direction of the semiconductor substrate is equal to or larger than the critical integrated concentration.

28. The manufacturing method of a semiconductor device according to claim 27, comprising:
performing the hydrogen ion implantation for forming the first lattice defect region after annealing for forming the first peak.

29. The manufacturing method of a semiconductor device according to claim 27, comprising:
simultaneously executing annealing for forming the first peak and annealing for forming the first lattice defect region after the hydrogen ion implantation for forming the first lattice defect region.

30. The manufacturing method of a semiconductor device according to claim 27, comprising:
executing annealing for forming the first lattice defect region at a lower temperature than in annealing for forming the first peak.

31. The manufacturing method of a semiconductor device according to claim 27, comprising:
executing annealing for forming the first lattice defect region in a shorter time than in annealing for forming the first peak.

32. The manufacturing method of a semiconductor device according to claim 27, wherein
a doping concentration of the first lattice defect region is lower than or equal to a doping concentration of the drift region.

33. The manufacturing method of a semiconductor device according to claim 27, wherein
a doping concentration of the first lattice defect region is lower than or equal to a bulk donor concentration.
